(19) United States
(12) Patent Application Publication
(10) Pub. No.: US 2025/0031552 A1
(43) Pub. Date: Jan. 23, 2025

(54) DISPLAY DEVICE AND METHOD OF FABRICATING THE SAME

(71) Applicant: Samsung Display Co., LTD., Yongin-si (KR)

(72) Inventors: Jeong Seok LEE, Yongin-si (KR); Woo Yong SUNG, Yongin-si (KR); Hee Jun YANG, Yongin-si (KR); Seung Yong SONG, Yongin-si (KR)

(21) Appl. No.: 18/584,297

(22) Filed: Feb. 22, 2024

(30) Foreign Application Priority Data
Jul. 20, 2023 (KR) 10-2023-0094280

(51) Int. Cl. H10K 59/80; H10K 59/12; H10K 59/122

(52) U.S. Cl. CPC H10K 59/873; H10K 59/1201; H10K 59/122

(57) ABSTRACT

A display device includes a first pixel electrode disposed on a substrate; a pixel defining layer disposed on the substrate and exposing the first pixel electrode; a first light emitting layer disposed on the first pixel electrode; a first common electrode disposed on the first light emitting layer; a first bank layer disposed on the pixel defining layer; a second bank layer disposed on the first bank layer and having side surfaces protruding more than side surfaces of the first bank layer; a first inorganic layer disposed on the first common electrode and the second bank layer and spaced apart from an upper surface of the second bank layer; and a first filler disposed between the second bank layer and the first inorganic layer and including a material different from a material of the first light emitting layer.

This application claims priority to Korean Patent Application No. 10-2023-0094280, filed on Jul. 20, 2023, and all the benefits accruing therefrom under 35 U.S.C. § 119, the content of which in its entirety is herein incorporated by reference.

### BACKGROUND

### 1. Field

Embodiments of the disclosure relate to a display device and a method of fabricating the display device.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among such flat panel display devices, a light emitting display device includes a light emitting element that enables each pixel of a display panel to emit light by itself. Thus, the light emitting display device can display an image without a backlight unit that provides light to the display panel.

Recently, display devices have been applied to glasses-like devices for providing virtual reality and augmented reality. To be applied to a glasses-like device, a display device may be desired to be implemented in a very small size of 2 inches or less. However, the display device may be desired to have a high pixel density to have high resolution. For example, the display device may be desired have a high pixel density of 400 pixels per inch (PPI) or greater.

### SUMMARY

When a display device is implemented in a very small size and to have a high pixel density to be applied to a glasses-like device, it may be difficult to implement a separate light emitting element in each emission area through a mask process because the area of the emission area in which the light emitting element is disposed is reduced.

Embodiments of the disclosure provide a display device in which a separate light emitting element can be formed in each emission area without a mask process.

Embodiments of the disclosure also provide a display device in which the etchant penetrates into the light emitting element during the etching process performed during the manufacturing process of the display device, reducing the variation in light emission that may occur for each pixel.

However, Embodiments of the disclosure are not restricted to the one set forth herein. The above and other features of embodiments of the disclosure will become more apparent to one of ordinary skill in the art to which the disclosure pertains by referencing the detailed description of the disclosure given below.

According to an embodiment of the disclosure, a display device includes a first pixel electrode disposed on a substrate; a pixel defining layer disposed on the substrate and exposing the first pixel electrode; a first light emitting layer disposed on the first pixel electrode; a first common electrode disposed on the first light emitting layer; a first bank layer disposed on the pixel defining layer; a second bank layer disposed on the first bank layer, where side surfaces of the second bank layer protrude more toward a center of a corresponding light emitting area than side surfaces of the first bank layer corresponding thereto do; a first inorganic layer disposed on the first common electrode and the second bank layer, where the first inorganic layer is spaced apart from an upper surface of the second bank layer; and a first filler disposed between the second bank layer and the first inorganic layer, where the first filler includes a material different from a material of the first light emitting layer.

In an embodiment, the first filler may include at least one selected from polyimide, polyamide, benzocyclobutene, a phenolic resin, an acrylic resin, a methacrylic resin, polyisoprene, a vinyl-based resin, an epoxy-based resin, a urethane-based resin, a cellulose-based resin, and a perylene-based resin.

In an embodiment, a width of the first filler may be in a range of about 3,000 angstroms (Å) to about 200,000 Å.

In an embodiment, a thickness of the first filler may be in a range of about 1,500 Å to about 2,500 Å.

In an embodiment, the display device may further include a second pixel electrode disposed on the substrate and spaced apart from the first pixel electrode; a second light emitting layer disposed on the second pixel electrode; a second common electrode disposed on the second light emitting layer and spaced apart from the first common electrode; a second inorganic layer disposed on the second common electrode and the second bank layer, where the second inorganic layer is spaced apart from the upper surface of the second bank layer; and a second filler disposed between the second bank layer and the second inorganic layer, where the second filler includes a material different from the second light emitting layer, where one end of the second bank layer may be adjacent to the first common electrode, an opposing other end of the second bank layer may be adjacent to the second common electrode, a width of the second bank layer may be a distance between the one end and the opposing end of the second bank layer, the first inorganic layer may include a wing portion spaced apart from the upper surface of the second bank layer and overlapping the second bank layer in a thickness direction of the substrate, and a ratio of a width of the wing portion of the first inorganic layer with respect to a width of the second bank layer may be in a range of 0.20 to 0.50.

In an embodiment, a ratio of a width of the first filler with respect to the width of the second bank layer may be in a range of 0.15 to 0.50.

In an embodiment, the first filler may include a first side surface adjacent to a side surface of the second bank layer, and a second side surface which is opposite to the first side surface, where the second side surface of the first filler may protrude more than the side surface of the first inorganic layer corresponding thereto.

In an embodiment, the first filler may include a first side surface adjacent to a side surface of the second bank layer, and a second side surface which may be a surface opposite to the first side surface, where the second side surface of the first filler may be aligned with a side surface of the first inorganic layer corresponding thereto to form a flat surface.

In an embodiment, the first filler may include a first side surface adjacent to a side surface of the second bank layer, and a second side surface which may be a surface opposite to the first side surface, where a side surface of the first inorganic layer may protrude more than the second side surface of the first filler corresponding thereto.

In an embodiment, the first inorganic layer may be in contact with a first side surface and the upper surface of the first filler, and a lower surface of the second bank layer.

In an embodiment, the display device may further include an organic encapsulation layer disposed on the first inorganic layer, where the organic encapsulation layer may include a material different from a material of the first filler.

In an embodiment, the first and second common electrodes may be spaced apart from each other, where the first and second common electrodes may be in contact with the side surfaces of the first bank layer.

In an embodiment, the display device may further include a residual pattern, wherein the pixel defining layer may be spaced apart from the upper surface of the first pixel electrode, and the residual pattern may be disposed between the pixel defining layer and the upper surface of the first pixel electrode.

According to an embodiment of the disclosure, a display device includes a first pixel electrode and a second pixel electrode, which are disposed on a substrate to be spaced apart from each other; a pixel defining layer disposed on the substrate and exposing the first pixel electrode and the second pixel electrode; a first light emitting layer disposed on the first pixel electrode, and a first common electrode disposed on the first light emitting layer; a second light emitting layer disposed on the second pixel electrode, and a second common electrode disposed on the second light emitting layer; a first bank layer disposed on the pixel defining layer; a second bank layer disposed on the first bank layer, where side surfaces of the second bank layer protrude more toward a center of a corresponding light emitting area than side surfaces of the first bank layer corresponding thereto do; a first inorganic layer disposed on the first common electrode and the second bank layer, where the first inorganic layer is spaced apart from an upper surface of the second bank layer; a second inorganic layer disposed on the second common electrode and the second bank layer, where the second inorganic layer is spaced apart from the upper surface of the second bank layer, and spaced apart from the first inorganic layer; and a first filler disposed between the second bank layer and the first inorganic layer, where the first filler includes a first side surface adjacent to a side surface of the second bank layer and a second side surface which is opposite to the first side surface, where the second side surface of the first filler protrudes more than a side surface of the first inorganic layer corresponding thereto.

In an embodiment, the display device may further include an organic encapsulation layer disposed on the first filler, the second bank layer and the first inorganic layer, wherein the second bank layer may be in contact with the first filler and the organic encapsulation layer.

In an embodiment, one end of the second bank layer may be adjacent to the first common electrode, an opposing end of the second bank layer may be adjacent to the second common electrode, a width of the second bank layer may be a distance between the one end and the other end of the second bank layer, a protrusion width of the first filler may be a width at which the second side surface of the first filler protrudes more than the side surface of the first inorganic layer, and a ratio of the protrusion width of the first filler with respect to the width of the second bank layer may be in a range of 0.02 to 0.20.

According to an embodiment of the disclosure, a display device includes a first pixel electrode and a second pixel electrode disposed to be spaced apart from each other on a substrate; a pixel defining layer disposed on the substrate and exposing the first pixel electrode and the second pixel electrode; a first light emitting layer disposed on the first pixel electrode, and a first common electrode disposed on the first light emitting layer; a second light emitting layer disposed on the second pixel electrode, and a second common electrode disposed on the second light emitting layer; a first bank layer disposed on the pixel defining layer; a second bank layer disposed on the first bank layer, where side surfaces of the second bank layer protrude more toward a center of a corresponding light emitting area than side surfaces of the first bank layer corresponding thereto do; a first inorganic layer disposed on the first common electrode and the second bank layer, where the first inorganic layer is spaced apart from an upper surface of the second bank layer; a second inorganic layer disposed on the second common electrode and the second bank layer, where the second inorganic layer is spaced apart from the upper surface of the second bank layer, and spaced apart from the first inorganic layer; and a first filler disposed between the second bank layer and the first inorganic layer, where the first filler includes a first side surface adjacent to a side surface of the second bank layer and a second side surface which is opposite to the first side surface, where a side surface of the first inorganic layer protrudes more than the second side surface of the first filler corresponding thereto.

In an embodiment, the display device may further include an organic encapsulation layer disposed on the first inorganic layer and the second inorganic layer, where the organic encapsulation layer may be in contact with a surface of the first inorganic layer facing the upper surface of the second bank layer.

According to an embodiment of the disclosure, a method of fabricating a display device includes forming pixel electrodes and sacrificial layers on a substrate, forming a pixel defining material layer on the sacrificial layers, forming a first bank material layer on the pixel defining material layer, and forming a second bank material layer on the first bank material layer, where the pixel electrodes are spaced apart from each other, and the sacrificial layers are disposed on the pixel electrodes; exposing the pixel defining material layer by etching portions of the first bank material layer and the second bank material layer in areas overlapping the pixel electrodes; etching side surfaces of the first bank material layer in a way such that portions of a lower surface of the second bank material layer are exposed; exposing the pixel electrodes by etching the exposed portion of the pixel defining material layer and the sacrificial layers; forming a first light emitting layer on a first pixel electrode of the pixel electrodes and forming a first organic material layer on the second bank material layer; forming a first common electrode on the first light emitting layer and forming a first electrode material layer on the first organic material layer; and forming a first inorganic material layer on the first common electrode and the first electrode material layer; exposing the first electrode material layer by etching a portion of the first inorganic material layer; exposing a second bank material layer by etching an exposed portion of the first electrode material layer and the first organic material layer; and forming a first filler on an exposed portion of the second bank material layer.

In an embodiment, the forming the first filler on the exposed second bank material layer may include applying a material of the first filler on the second bank material layer through slit coating, spin coating, or inkjet printing; filling between the second bank material layer and the first inorganic material layer with a material of the first filler through a capillary action; and patterning the first filler through a photolithography process.

In an embodiment, the forming the first light emitting layer on the first pixel electrode of the pixel electrodes and the forming the first organic material layer on the second bank material layer may include cutting an organic material deposited on the substrate by a protruding side surface of the second bank material layer to be disconnected from the first light emitting layer and the first organic material layer.

In an embodiment, the exposing the first electrode material layer by etching a portion of the first inorganic material layer may include removing the portion of the first inorganic material layer through a dry etching process, and the exposing the second bank material layer by etching the exposed portion of the first electrode material layer and the first organic material layer may include removing the exposed portion of the first electrode material layer and the first organic material layer through a wet etching process.

In a display device and a method of fabricating the display device according to embodiments of the disclosure, by including a filler between a first inorganic encapsulation layer and a bank structure, etchant radicals may be effectively prevented from infiltrating between a second bank layer and the first inorganic encapsulation layer during the etching process. Accordingly, in such embodiments, the damage of the light emitting element due to the etchant or moisture may be effectively prevented and illuminance difference between the light emitting elements may be reduced.

However, effects according to the embodiments of the disclosure are not limited to those exemplified above and various other effects are incorporated herein.

### BRIEF DESCRIPTION OF THE DRAWINGS

The above and other features of the invention will become more apparent by describing in further detail embodiments thereof with reference to the accompanying drawings, in which:

FIG. 1 is a perspective view illustrating a display device according to an embodiment;

FIG. 2 is a cross-sectional view of the display device of FIG. 1 as viewed from the side;

FIG. 3 is a plan view illustrating the arrangement of light emitting elements, first inorganic encapsulation layers, fillers, and a second bank layer of the display device according to the embodiment;

FIG. 4 is a cross-sectional view illustrating a portion of the display device according to the embodiment;

FIG. 5 is an enlarged view illustrating a first emission area and a second emission area, specifically, area A1 of FIG. 4;

FIG. 6 is an enlarged view of a display device according to another embodiment;

FIG. 7 is an enlarged view of a display device according to still another embodiment;

FIG. 8 is a cross-sectional view illustrating that an etchant permeates into a light emitting element when there is no filler; and

FIGS. 9 to 20 are cross-sectional views sequentially illustrating processes for fabrication of the display device according to an embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

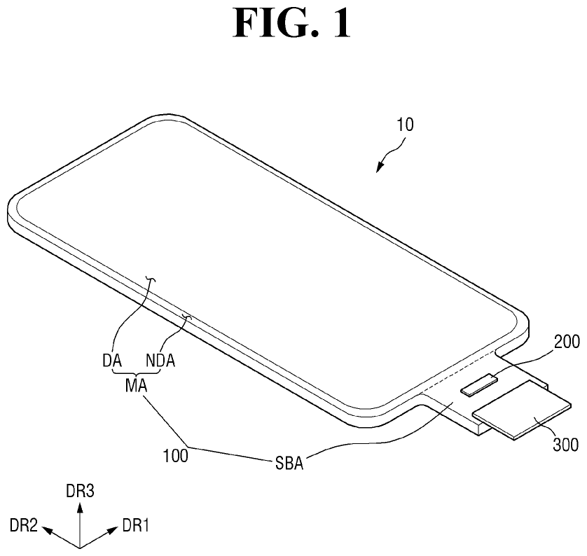

FIG. 1 is a perspective view illustrating a display device according to an embodiment.

Referring to FIG. 1, a display device 10 according to an embodiment may be included in an electronic device provided with a screen thereon. The electronic device may refer to all electronic devices that provide display screens, for example, televisions, laptop computers, monitors, billboards, the Internet of Things (IoT), mobile phones, smartphones, tablet personal computers (PCs), electronic watches, smart glasses, smart watches, watch phones, head mounted displays, mobile communication terminals, electronic notebooks, electronic books, portable multimedia players (PMPs), navigation devices, game machines, digital cameras, camcorders, and the like, which provide display screens, may be included in the electronic device.

A shape of the display device 10 may be variously modified. In an embodiment, for example, the display device 10 may have a shape similar to a rectangular shape having short sides in a first direction DR1 and long sides in the second direction DR2. A third direction DR3, which is perpendicular to the first direction DR1 and the second direction DR2, may be a thickness direction of the display device 10. A corner where the short side in the first direction DR1 and the long side in the second direction DR2 meet may be rounded with a curvature, but is not limited thereto, and may also be right-angled. The shape of the display device 10 in plan view is not limited to the rectangular shape, and may be a shape similar to other polygonal shapes, a circular shape, or an elliptical shape.

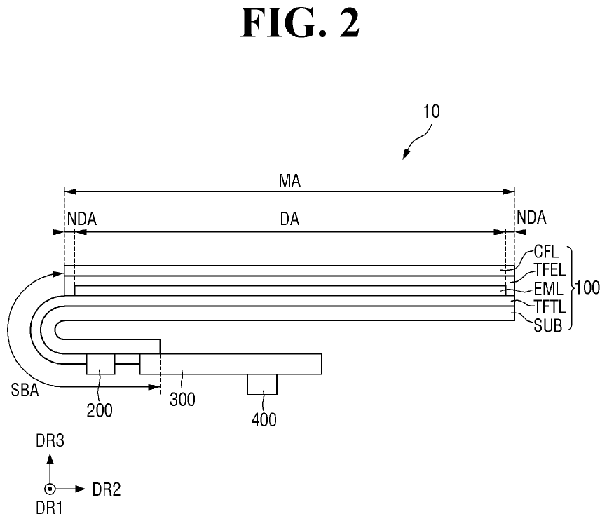

The display device 10 may include a display panel 100, a display driver 200, a circuit board 300, and a touch driver 400 (shown in FIG. 2).

The display panel 100 may include a main area MA and a sub-area SBA.

The main area MA may include a display area DA including pixels for displaying an image and a non-display area NDA disposed around the display area DA. The display area DA may emit light from a plurality of emission areas or a plurality of opening areas. In an embodiment, for example, the display panel 100 may include pixel circuits including switching elements, a pixel defining layer defining the emission areas or the opening areas, and self-light emitting elements.

For example, the self-light emitting element may include at least one selected from an organic light emitting diode (LED) including an organic light emitting layer, a quantum dot LED including a quantum dot light emitting layer, an inorganic LED including an inorganic semiconductor, and a micro LED, but is not limited thereto.

A plurality of pixels, a plurality of scan lines, a plurality of data lines, and a plurality of power lines may be disposed in the display area DA. Each of the plurality of pixels may be defined as a minimum unit for emitting light, and each of the self-light emitting elements described above may be each of the pixels. The plurality of scan lines may supply scan signals received from a scan driver to the plurality of pixels. The plurality of data lines may supply data voltages received from the display driver 200 to the plurality of pixels. The plurality of power lines may supply source voltages received from the display driver 200 to the plurality of pixels.

The non-display area NDA may be an area outside the display area DA. The non-display area NDA may be defined as an edge area of the main area MA of the display panel 100. The non-display area NDA may include the scan driver for supplying the scan signals to the scan lines, and fan-out lines for connecting the display driver 200 and the display area DA to each other.

The sub-area SBA may be an area extending from one side of the main area MA. The sub-area SBA may include a flexible material that may be bent, folded, and rolled. In an embodiment, for example, when the sub-area SBA is bent, the sub-area SBA may overlap the main area MA in a thickness direction (the third direction DR3). The sub-area SBA may include the display driver 200 and pad parts connected to the circuit board 300. In another embodiment, the sub-area SBA may be omitted, and the display driver 200 and the pad parts may be disposed in the non-display area NDA.

The display driver 200 may output signals and voltages for driving the display panel 100. The display driver 200 may supply the data voltages to the data lines. The display driver 200 may supply the source voltages to the power lines and supply scan control signals to the scan driver. The display driver 200 may be formed as an integrated circuit (IC) and mounted on the display panel 100 in a chip on glass (COG) manner, a chip on plastic (COP) manner, or an ultrasonic bonding manner. in an embodiment, for example, the display driver 200 may be disposed in the sub-area SBA, and may overlap the main area MA in the thickness direction (the third direction DR3) by bending of the sub-area SBA. In an embodiment, for example, the display driver 200 may be mounted on the circuit board 300.

The circuit board 300 may be attached onto the pad parts of the display panel 100 using an anisotropic conductive film (ACF). Lead lines of the circuit board 300 may be electrically connected to the pad parts of the display panel 100. The circuit board 300 may be a flexible printed circuit board, a printed circuit board, or a flexible film such as a chip on film.

FIG. 2 is a cross-sectional view of the display device of FIG. 1 as viewed from the side. Specifically, FIG. 2 illustrates a side surface of the display device of FIG. 1 in a state in which the display device is folded.

Referring to FIG. 2, in an embodiment, the display panel 100 may include a substrate SUB, a thin film transistor layer TFTL, a light emitting element layer EML, a thin film encapsulation layer TFEL, and a color filter layer CFL.

The substrate SUB may be a base substrate or a base member. The substrate SUB may be a flexible substrate that may be bent, folded, and rolled. In an embodiment, for example, the substrate SUB may include a polymer resin such as polyimide (PI), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include scan lines, data lines, power lines, scan control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. In an embodiment, for example, where the scan driver is provided or formed on one side of the non-display area NDA of the display panel 100, the scan driver may include thin film transistors.

The thin film transistor layer TFTL may be disposed in the display area DA, the non-display area NDA, and the sub-area SBA. The thin film transistors of each of the pixels, the scan lines, the data lines, and the power lines of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements, each including a first electrode, a second electrode, and a light emitting layer to emit light and a pixel defining layer defining the pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In another embodiment, the light emitting element may include a quantum dot LED including a quantum dot light emitting layer, an inorganic LED including an inorganic semiconductor, or a micro LED.

The thin film encapsulation layer TFEL may cover an upper surface and side surfaces of the light emitting element layer EML, and may protect the light emitting element layer EML. The thin film encapsulation layer TFEL may include at least one inorganic layer and at least one organic layer for encapsulating the light emitting element layer EML.

The color filter layer CFL may be disposed on the thin film encapsulation layer TFEL. The color filter layer CFL may include a plurality of color filters each corresponding to the plurality of emission areas. Each of the color filters may selectively transmit light of a specific wavelength therethrough and block or absorb light of other wavelengths. The color filter layer CFL may absorb some of light introduced from the outside of the display device 10 to reduce reflected light by external light. Accordingly, the color filter layer CFL may effectively prevent distortion of colors due to external light reflection.

In an embodiment where the color filter layer CFL is directly disposed on the thin film encapsulation layer TFEL, the display device 10 may not include a separate substrate for the color filter layer CFL. Accordingly, a thickness of the display device 10 may be relatively thin.

In some embodiments, the display device 10 may further include an optical device. The optical device may emit or receive light of infrared, ultraviolet, and visible light bands. In an embodiment, for example, the optical device may be an optical sensor sensing light incident on the display device 10, such as a proximity sensor, an illuminance sensor, a camera sensor, a fingerprint sensor, or an image sensor.

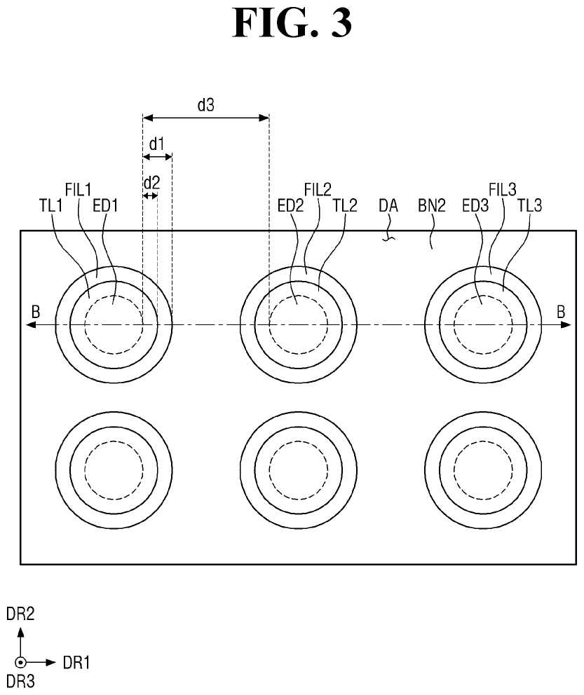

FIG. 3 is a plan view illustrating a portion of the display device according to an embodiment. FIG. 3 is a plan view illustrating an arrangement of light emitting elements ED1, ED2, and ED3, first inorganic encapsulation layers TL1, TL2, and TL3, fillers FIL1, FIL2, and FIL3, and a second bank layer BN2 in the display area DA of the display device 10.

Referring to FIG. 3, in an embodiment, the second bank layer BN2 may cover the display area DA, but expose portions of the display area DA. Openings (dotted line areas in FIG. 3) may be defined or formed in exposed areas that are not covered with the second bank layer BN2, and the light emitting elements ED1, ED2, and ED3 may be disposed within the respective openings. The first inorganic encapsulation layers TL1, TL2, and TL3 may cover the light emitting elements ED1, ED2, and ED3 within the openings, and may partially cover boundary portions of the openings, or side surfaces of the second bank layer BN2 and the fillers FIL1, FIL2, and FIL3 that define the openings. Portions of the first inorganic encapsulation layers TL1, TL2, and TL3 that covers the boundary portions of the opening may be referred to as wing portions and each of the wing portions may have a width d2 of a predetermined distance. In an embodiment, as shown in FIG. 3, a width d1 of each of the fillers FIL1, FIL2, and FIL3 may be greater than the width d2 of the wing portion of each of the first inorganic encapsulation layers TL1, TL2, and TL3, but the disclosure is not limited thereto.

In an embodiment, as illustrated in FIG. 3, the exposed areas that are not covered with the second bank layer BN2 may have a circular shape, but not being limited thereto. In an embodiment, the exposed areas that are not covered with the second bank layer BN2 may have a polygonal shape such as a triangular shape, a quadrangular shape, or a hexagonal shape, and a shape of the first inorganic encapsulation layers TL1, TL2, and TL3 covering the exposed areas and peripheral portions of the exposed areas may also be changed or modified. Portions (wings) of the first inorganic encapsulation layers TL1, TL2, and TL3 and the fillers FIL1, FIL2, and FIL3 may be disposed at a level above the second bank layer BN2, and the light emitting elements ED1, ED2, and ED3 may be disposed at a level below the second bank layer BN2.

The exposed areas that are not covered with the second bank layer BN2 may be disposed to be spaced apart from each other in the first direction DR1 and may also be disposed to be spaced apart from each other in the second direction DR2. A shape and an arrangement of the exposed areas that are not covered with the second bank layer BN2 are not limited to those illustrated in FIG. 3, and the exposed areas that are not covered with the second bank layer BN2 may be disposed in a PENTILE™ type.

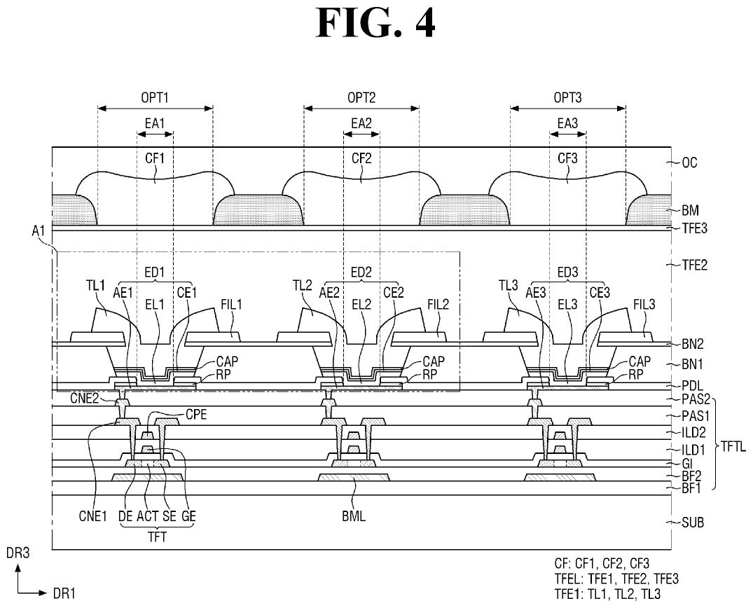

FIG. 4 is a cross-sectional view illustrating a portion of the display device according to the embodiment. Specifically, FIG. 4 is a cross-sectional view taken along line B-B of FIG. 3, and illustrates an organic encapsulation layer TFE2, a second inorganic encapsulation layer TFE3, color filters CF1, CF2, and CF3, a light blocking layer BM, and an overcoat layer OC that are disposed above the plan view of FIG. 3. FIG. 4 illustrates cross sections of the substrate SUB, the thin film transistor layer TFTL, the light emitting element layer EML, the thin film encapsulation layer TFEL, and the color filter layer CFL.

In an embodiment, the thin film transistor layer TFTL may include a first buffer layer BF1, a bottom metal layer BML, a second buffer layer BF2, thin film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer capable of preventing permeation of air or moisture. In an embodiment, for example, the first buffer layer BF1 may include a plurality of inorganic layers that are alternately stacked.

The bottom metal layer BML may be disposed on the first buffer layer BF1. In an embodiment, for example, the bottom metal layer BML may be formed as a single layer or multiple layers, each layer therein including or made of at least one selected from molybdenum (Mo), aluminum (Al), chromium (Cr), gold (Au), titanium (Ti), nickel (Ni), neodymium (Nd), and copper (Cu), and a combination (e.g., alloys) thereof.

The second buffer layer BF2 may cover the first buffer layer BF1 and the bottom metal layer BML. The second buffer layer BF2 may include an inorganic layer capable of preventing permeation of air or moisture. In an embodiment, for example, the second buffer layer BF2 may include a plurality of inorganic layers that are alternately stacked.

The thin film transistor TFT may be disposed on the second buffer layer BF2, and may constitute a pixel circuit of each of the plurality of pixels. In an embodiment, for example, the thin film transistor TFT may be a driving transistor or a switching transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML and the gate electrode GE in the thickness direction DR3, and may be insulated from the gate electrode GE by the gate insulating layer GI. A material of the semiconductor layer ACT in portions of the semiconductor layer ACT may become conductors to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed therebetween.

The gate insulating layer GI may be disposed on the semiconductor layer ACT. In an embodiment, for example, the gate insulating layer GI may cover the semiconductor layer ACT and the second buffer layer BF2, and may insulate the semiconductor layer ACT and the gate electrode GE from each other. The gate insulating layer GI may be provided with contact holes through which the first connection electrodes CNE1 extend.

The first interlayer insulating layer ILD1 may cover the gate electrode GE and the gate insulating layer GI. The first interlayer insulating layer ILD1 may be provided with contact holes through which the first connection electrodes CNE1 extend. The contact holes of the first interlayer insulating layer ILD1 may be connected to the contact holes of the gate insulating layer GI and contact holes of the second interlayer insulating layer ILD2.

The capacitor electrodes CPE may be disposed on the first interlayer insulating layer ILD1. The capacitor electrode CPE may overlap the gate electrode GE in the thickness direction DR3. The capacitor electrode CPE and the gate electrode GE may form capacitance.

The second interlayer insulating layer ILD2 may cover the capacitor electrodes CPE and the first interlayer insulating layer ILD1. The second interlayer insulating layer ILD2 may be provided with contact holes through which the first connection electrodes CNE1 extend. The contact holes of the second interlayer insulating layer ILD2 may be connected to the contact holes of the first interlayer insulating layer ILD1 and the contact holes of the gate insulating layer GI.

The first connection electrodes CNE1 may be disposed on the second interlayer insulating layer ILD2. The first connection electrode CNE1 may electrically connect the drain electrode DE of the thin film transistor TFT and the second connection electrode CNE2 to each other. The first connection electrode CNE1 may be inserted into the contact holes defined or formed in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may be provided with contact holes through which the second connection electrodes CNE2 extend.

The second connection electrodes CNE2 may be disposed on the first passivation layer PAS1. The second connection electrodes CNE2 may electrically connect the first connection electrodes CNE1 and pixel electrodes AE1, AE2, and AE3 of the light emitting elements ED to each other. The second connection electrode CNE2 may be inserted into the contact hole defined or formed in the first passivation layer PAS1 to be in contact with the first connection electrode CNE1.

The second passivation layer PAS2 may cover the second connection electrodes CNE2 and the first passivation layer PAS1. The second passivation layer PAS2 may be provided with contact holes through which the pixel electrodes AE1, AE2, and AE3 of the light emitting elements ED extend.

The light emitting element layer EML may be disposed on the thin film transistor layer TFTL. The light emitting element layer EML may include light emitting elements ED, a pixel defining layer PDL, capping layers CAP, and a bank structure BNS. The light emitting elements ED may include the pixel electrodes AE1, AE2, and AE3, light emitting layers EL1, EL2, and EL3, and common electrodes CE1, CE2, and CE3.

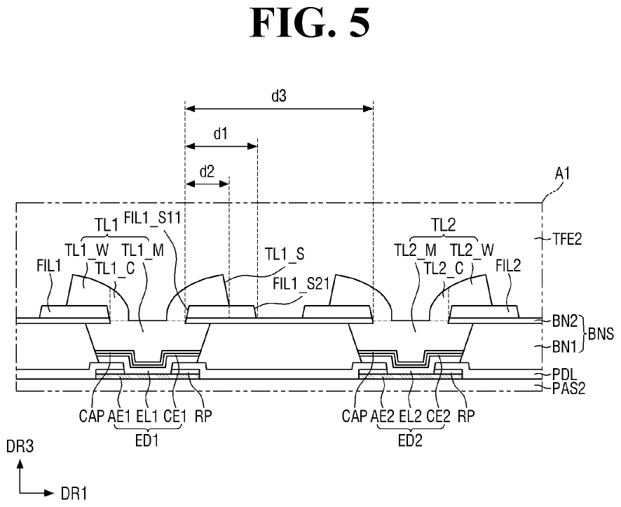

FIG. 5 is an enlarged view illustrating a first emission area and a second emission area, specifically, area A1 of FIG. 4.

Referring to FIG. 5 in addition FIG. 4, in an embodiment, the display device 10 may include a plurality of emission areas EA1, EA2, and EA3 disposed or defined in the display area DA. The emission areas EA1, EA2, and EA3 may include areas in which light is emitted from the light emitting elements ED1, ED2, and ED3 and passes to the color filter layer CFL in the third direction DR3. The emission areas EA1, EA2, and EA3 may include first emission areas EA1, second emission areas EA2, and third emission areas EA3 that are spaced apart from each other and emit light of a same color as each other or different colors from each other.

In an embodiment, areas or sizes of the first to third emission areas EA1, EA2, and EA3 may be the same as each other. In an embodiment, for example, in the display device 10, the first emission area EA1, the second emission area EA2, and the third emission area EA3 may have a same area as each other. However, the disclosure is not limited thereto. In an embodiment of the display device 10, areas or sizes of the first to third emission areas EA1, EA2, and EA3 may be different from each other. In an embodiment, for example, an area of the second emission area EA2 may be greater than areas of the first emission area EA1 and the third emission area EA3, and an area of the third emission area EA3 may be greater than an area of the first emission area EA1. Intensities of the light emitted from the emission areas EA1, EA2, and EA3 may be changed depending on the areas of the emission areas EA1, EA2, and EA3, and a color feeling of a screen displayed on the display device 10 may be controlled by adjusting the areas of the emission areas EA1, EA2, and EA3. FIG. 4 shows an embodiment where the areas of the emission areas EA1, EA2, and EA3 are the same as each other, but the disclosure is not limited thereto.

In an embodiment of the display device 10, one first emission area EA1, one second emission area EA2, and one third emission area EA3 disposed adjacent to each other may form one pixel group. One pixel group may include the emission areas EA1, EA2, and EA3 emitting light of different colors to express a white gradation. However, the disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, and the like.

A plurality of openings formed in the bank structure BNS of the light emitting element layer EML are defined along a boundary of the bank structure BNS. A first bank layer BN1 and a second bank layer BN2 of the bank structure BNS may have a shape which surrounds the emission areas EA1, EA2, and EA3. The openings may include the first to third emission areas EA1, EA2, and EA3.

The display device 10 may include a plurality of light emitting elements ED1, ED2, and ED3 disposed in respective emission areas EA1, EA2, and EA3. The light emitting elements ED1, ED2, and ED3 may include a first light emitting element ED1 disposed in the first emission area EA1, a second light emitting element ED2 disposed in the second emission area EA2, and a third light emitting element ED3 disposed in the third emission area EA3.

The light emitting elements ED1, ED2, and ED3 may include pixel electrodes AE1, AE2, and AE3, light emitting layers EL1, EL2, and EL3, and common electrodes CE1, CE2, and CE3, respectively, and the light emitting elements ED1, ED2, and ED3 disposed in the respective emission areas EA1, EA2, and EA3 may emit light of different colors depending on materials of the light emitting layers EL1, EL2, and EL3, respectively. In an embodiment, for example, the first light emitting element ED1 disposed in the first emission area EA1 may emit first light, which is red light, having a peak wavelength in a range of about 610 nanometers (nm) to about 650 nm, the second light emitting element ED2 disposed in the second emission area EA2 may emit second light, which is green light, having a peak wavelength in a range of about 510 nm to about 550 nm, and the third light emitting element ED3 disposed in the third emission area EA3 may emit third light, which is blue light, having a peak wavelength in a range of about 440 nm to about 480 nm. The first to third emission areas EA1, EA2, and EA3 constituting one pixel may include the light emitting elements ED1, ED2, and ED3 emitting the light of the different colors to express a white gradation. Alternatively, the light emitting layers EL1, EL2, and EL3 may include two or more materials for emitting the light of the different colors, such that one light emitting layer may emit mixed light. In an embodiment, for example, the light emitting layers EL1, EL2, and EL3 may include both of a red light emitting material and a green light emitting material to emit yellow light or include all of a red light emitting material, a green light emitting material, and a blue light emitting material to emit white light.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be disposed to be spaced apart from each other on the second passivation layer PAS2, respectively. In an embodiment, as illustrated in FIG. 4, the first to third pixel electrodes AE1, AE2, and AE3 may be spaced apart from each other in the first direction DR1, but the disclosure is not limited thereto, and the first to third pixel electrodes AE1, AE2, and AE3 may be spaced apart from each other in any one direction within a plane formed by the first direction DR1 and the second direction DR2.

The pixel electrodes AE1, AE2, and AE3 may be electrically connected to the drain electrodes DE of the thin film transistors TFT through the first and second connection electrodes CNE1 and CNE2. Edges of the pixel electrodes AE1, AE2, and AE3 spaced apart from each other are covered by the pixel defining layer PDL, such that the first to third pixel electrodes AE1, AE2, and AE3 may be insulated from each other.

The pixel electrodes AE1, AE2, and AE3 may include a transparent electrode material and/or a conductive metal material. The conductive metal material may include at least one selected from silver (Ag), copper (Cu), aluminum (Al), nickel (Ni), lanthanum (La), titanium (Ti), and titanium nitride (TiN). The transparent electrode material may include at least one selected from indium tin oxide (ITO), indium zinc oxide (IZO), and indium tin zinc oxide (ITZO). The pixel electrodes AE1, AE2, and AE3 may have a multilayer structure including the transparent electrode material and the conductive metal material.

The pixel defining layer PDL may be disposed on the second passivation layer PAS2, residual patterns RP, and the pixel electrodes AE1, AE2, and AE3. The pixel defining layer PDL may be entirely disposed on the second passivation layer PAS2, but may expose portions of upper surfaces of the pixel electrodes AE1, AE2, and AE3 by covering side surfaces of the pixel electrodes AE1, AE2, and AE3 and the residual patterns RP. In an embodiment, for example, the pixel defining layer PDL may expose the first pixel electrode AE1 in the first emission area EA1, and a first light emitting layer EL1 may be directly disposed on the first pixel electrode AE1.

The pixel defining layer PDL may include an inorganic insulating material. The pixel defining layer PDL may include at least one selected from a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but is not limited thereto.

According to an embodiment, the pixel defining layer PDL may be disposed on the pixel electrodes AE1, AE2, and AE3, but may be spaced apart from the upper surfaces of the pixel electrodes AE1, AE2, and AE3. The pixel defining layer PDL may not be in direct contact with the upper surfaces of the pixel electrodes AE1, AE2, and AE3 while partially overlapping the upper surfaces of the pixel electrodes AE1, AE2, and AE3 in the thickness direction DR3 of the substrate SUB, and the residual patterns RP may be disposed between the pixel defining layer PDL and the pixel electrodes AE1, AE2, and AE3. However, the pixel defining layer PDL may be in direct contact with side surfaces of the pixel electrodes AE1, AE2, and AE3. Side surfaces of the pixel defining layer PDL may protrude more than side surfaces of the second bank layer BN2 toward the emission areas EA1, EA2, and EA3.

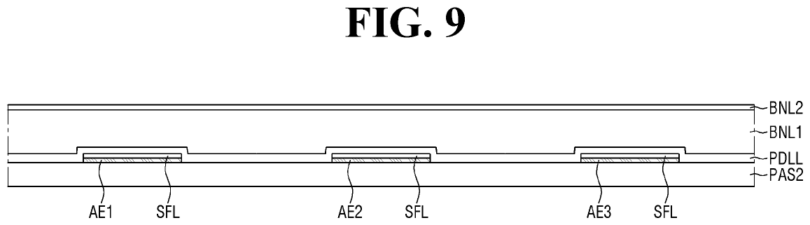

The residual patterns RP may be disposed on edges of the pixel electrodes AE1, AE2, and AE3, respectively. The pixel defining layer PDL may not be in direct contact with the upper surfaces of the pixel electrodes AE1, AE2, and AE3 due to the residual patterns RP. The residual patterns RP may be formed by removing portions of sacrificial layers SFL (see FIG. 9) disposed on the pixel electrodes AE1, AE2, and AE3 in processes of fabrication of the display device 10. The residual pattern RP may include a metal, an oxide semiconductor, or a transparent conductive oxide (TCO). Embodiment where side surfaces of the residual patterns RP toward the emission areas EA1, EA2, and EA3 are aligned with the side surfaces of the pixel defining layer PDL are illustrated in the drawings, but the disclosure is not limited thereto. The side surfaces of the residual patterns RP may protrude more than the side surfaces of the pixel defining layer PDL toward a center of a corresponding one of the emission areas EA1, EA2, and EA3 or may be depressed more than the side surfaces of the pixel defining layer PDL.

The light emitting layers EL1, EL2, and EL3 may be disposed on the pixel electrodes AE1, AE2, and AE3, respectively. The light emitting layers EL1, EL2, and EL3 may be organic light emitting layers formed or made of an organic material, and may be formed on the pixel electrodes AE1, AE2, and AE3, respectively, through a deposition process. The light emitting layers EL1, EL2, and EL3 may have a multilayer structure, and a hole injection material, a hole transporting material, a light emitting material, an electron transporting material, and/or an electron injection material may constitute layers of the light emitting layers EL1, EL2, and EL3, respectively. When the thin film transistors TFT apply predetermined voltages to the pixel electrodes AE1, AE2, and AE3 of the light emitting elements ED1, ED2, and ED3 and the common electrodes CE1, CE2, and CE3 of the light emitting elements ED1, ED2, and ED3 receives a common voltage or a cathode voltage, holes and electrons may be injected and transported, respectively, and may be combined with each other in the light emitting layers EL1, EL2, and EL3 to emit light.

The light emitting layers EL1, EL2, and EL3 may include a first light emitting layer EL1, a second light emitting layer EL2, and a third light emitting layer EL3, each disposed in the respective emission areas EA1, EA2, and EA3. The first light emitting layer EL1 may be disposed on the first pixel electrode AE1 in the first emission area EA1, the second light emitting layer EL2 may be disposed on the second pixel electrode AE2 in the second emission area EA2, and the third light emitting layer EL3 may be disposed on the third pixel electrode AE3 in the third emission area EA3. A plurality of light emitting layers EL1, EL2, and EL3 may emit light of different colors, respectively, or one light emitting layer EL1, EL2, or EL3 may emit mixed light. In an embodiment, the first light emitting layer EL1 may emit red light, the second light emitting layer EL2 may emit green light, and the third light emitting layer EL3 may emit blue light. In another embodiment, the first light emitting layer EL1 may emit yellow light, which is mixed light of red light and green light, and the second light emitting layer EL2 may emit blue light. In still another embodiment, the first light emitting layer EL1 may emit white light, which is mixed light of red light, green light, and blue light.

In an embodiment, a thickness h2 of the light emitting layers EL1, EL2, and EL3 may be in a range of about 1,500 angstroms (Å) to about 2,500 Å. The thickness of the light emitting layers EL1, EL2, and EL3 may be changed depending on the light emitted from the light emitting layers EL1, EL2, and EL3.

The light emitting layers EL1, EL2, and EL3 may be disposed on an upper surface of the pixel defining layer PDL. The light emitting layers EL1, EL2, and EL3 may be disposed in spaces between the pixel electrodes AE1, AE2, and AE3 and the pixel defining layer PDL. The light emitting layers EL1, EL2, and EL3 may be in contact with the pixel defining layer PDL, the residual patterns RP, and the pixel electrodes AE1, AE2, and AE3.

The common electrodes CE1, CE2, and CE3 may be disposed on the light emitting layers EL1, EL2, and EL3, respectively. The common electrodes CE1, CE2, and CE3 may include a transparent conductive material to emit the light generated from the light emitting layers EL1, EL2, and EL3. The common electrodes CE1, CE2, and CE3 may receive a common voltage or a low potential voltage. When the pixel electrodes AE1, AE2, and AE3 receive voltages corresponding to data voltages and the common electrodes CE1, CE2, and CE3 receive the low potential voltage, potential differences are formed between the pixel electrodes AE1, AE2, and AE3 and the common electrodes CE1, CE2, and CE3, such that the light emitting layers EL1, EL2, and EL3 may emit the light.

The common electrodes CE1, CE2, and CE3 may include a first common electrode CE1, a second common electrode CE2, and a third common electrode CE3 each disposed in the respective emission areas EA1, EA2, and EA3. The first common electrode CE1 may be disposed on the first light emitting layer EL1 in the first emission area EA1, the second common electrode CE2 may be disposed on the second light emitting layer EL2 in the second emission area EA2, and the third common electrode CE3 may be disposed on the third light emitting layer EL3 in the third emission area EA3. The first to third common electrodes CE1, CE2, and CE3 may be spaced apart from each other.

The capping layers CAP may be disposed on the common electrodes CE1, CE2, and CE3. The capping layers CAP may include an organic or inorganic insulating material and cover patterns disposed on the light emitting elements ED1, ED2, and ED3. The capping layers CAP may prevent the light emitting elements ED1, ED2, and ED3 from being damaged by external air. In an embodiment, the capping layer CAP may include an organic material such as α-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The display device 10 may include a plurality of bank structures BNS disposed on the pixel defining layer PDL. The bank structure BNS may have a structure in which bank layers BN1 and BN2 including different materials are sequentially stacked, may include the plurality of openings including the emission areas EA1, EA2, and EA3, and may be disposed so as to overlap a light blocking layer BM to be described later. The light emitting elements ED1, ED2, and ED3 of the display device 10 may be disposed to overlap the openings of the bank structure BNS.

The bank structure BNS may include a first bank layer BN1 and a second bank layer BN2 that are sequentially stacked on the pixel defining layer PDL.

The first bank layer BN1 may be disposed on the pixel defining layer PDL. Side surfaces of the first bank layer BN1 may be depressed more than side surfaces of the pixel defining layer PDL in a direction opposite to a direction toward the center of the corresponding one of the emission areas EA1, EA2, and EA3. The side surfaces of the first bank layer BN1 may be depressed more than side surfaces of a second bank layer BN2 to be described later in the direction opposite to the direction toward the center of the corresponding one of the emission areas EA1, EA2, and EA3.

According to an embodiment, the first bank layer BN1 may include a metal material. In an embodiment, the first bank layer BN1 may include aluminum (Al) or an alloy of aluminum (Al).

In an embodiment, a thickness of the first bank layer BN1 may be in a range of about 4,000 Å to about 7,000 Å. In such an embodiment where the thickness of the first bank layer BN1 is in the above range, the light emitting layers EL1, EL2, and EL3 and the common electrodes CE1, CE2, and CE3 spaced apart from each other may be effectively formed through deposition and etching processes without using a mask process.

According to an embodiment, the common electrodes CE1, CE2, and CE3 may be in direct contact with the side surfaces of the first bank layer BN1. The common electrodes CE1, CE2, and CE3 of different light emitting elements ED1, ED2, and ED3 may be in direct contact with the first bank layer BN1, respectively, and the first bank layer BN1 may include the metal material, such that the common electrodes CE1, CE2, and CE3 may be electrically connected to each other through the first bank layer BN1.

The light emitting layers EL1, EL2, and EL3 may be in direct contact with the side surfaces of the first bank layer BN1. A contact area between the common electrodes CE1, CE2, and CE3 and the side surfaces of the first bank layer BN1 may be greater than a contact area between the light emitting layers EL1, EL2, and EL3 and the side surfaces of the first bank layer BN1. The common electrodes CE1, CE2, and CE3 may be disposed to have a greater area than the light emitting layers EL1, EL2, and EL3 on the side surfaces of the first bank layer BN1 or may be disposed up to a greater height than the light emitting layers EL1, EL2, and EL3 on the side surfaces of the first bank layer BN1. Since the common electrodes CE1, CE2, and CE3 of the different light emitting elements ED1, ED2, and ED3 are electrically connected to each other through the first bank layer BN1, it may be advantageous that the common electrodes CE1, CE2, and CE3 are in contact with the first bank layer BN1 in a greater area.

The second bank layer BN2 may be disposed on the first bank layer BN1. The second bank layer BN2 may include tips TIP, which are areas protruding more toward the center of the corresponding one of the emission areas EA1, EA2, and EA3 than the first bank layer BN1. The side surfaces of the second bank layer BN2 may protrude more than the side surfaces of the first bank layer BN1 toward the center of the corresponding one of the emission areas EA1, EA2, and EA3, that is, the side surfaces of the second bank layer BN2 may protrude more toward the center of the corresponding one of the emission areas EA1, EA2, and EA3 than the side surfaces of the first bank layer BN1 do.

The side surfaces of the second bank layer BN2 have a shape in which they protrude more than the side surfaces of the first bank layer BN1 toward the center of the corresponding one of the emission areas EA1, EA2, and EA3, and accordingly, undercut structures of the first bank layer BN1 may be formed under the tips TIP of the second bank layer BN2.

In the display device 10 according to an embodiment, the bank structure BNS includes the tips TIP protruding toward the center of the corresponding one of the emission areas EA1, EA2, and EA3, and thus, the light emitting layers EL1, EL2, and EL3 and the common electrodes CE1, CE2, and CE3 may be formed through deposition and etching processes without using a mask process. In such an embodiment, it is possible to form different layers individually in the different emission areas EA1, EA2, and EA3 even through a deposition process. In an embodiment, for example, even though the light emitting layers EL1, EL2, and EL3 and the common electrodes CE1, CE2, and CE3 of the light emitting elements ED1, ED2, and ED3 are formed through a deposition process that does not use a mask, deposited materials may be disconnected from each other with the bank structure BNS interposed therebetween by the tips TIP of the second bank layer BN2 rather than being connected to each other between the emission areas EA1, EA2, and EA3. It is possible to form the different layers individually in the different emission areas EA1, EA2, and EA3 through a process of forming a material for forming a specific layer on the entire surface of the display device 10 and then etching and removing a layer formed in unwanted areas. In such an embodiment of the display device 10, through the deposition and etching processes without using the mask process, the different light emitting elements ED1, ED2, and ED3 may be formed for each of the emission areas EA1, EA2, and EA3, an undesired component may be omitted from the display device 10, and an area of the non-display area NDA may be minimized.

A side surface shape of the bank structure BNS may be a structure formed due to a difference in etch rate between the first and second bank layers BN1 and BN2 in an etching process because the first and second bank layers BN1 and BN2 include different materials from each other. According to an embodiment, the second bank layer BN2 may include a material having an etch rate slower (or lower) than that of the first bank layer BN1, and the first bank layer BN1 may be further etched in the etching process, such that lower surfaces of the tips TIP of the second bank layer BN2 may be exposed and undercuts may be formed under the tips TIP of the second bank layer BN2.

The second bank layer BN2 may include a metal material different from the metal material of the first bank layer BN1. The metal material of the second bank layer BN2 may be any material that is removed together with the metal material of the first bank layer BN1 by dry etching, but has an etch rate substantially slower than that of the first bank layer BN1 or is not etched with respect to wet etching. In an embodiment, the first bank layer BN1 may include aluminum (Al), and the second bank layer BN2 may include titanium (Ti).

The tips TIP of the second bank layer BN2 may overlap the common electrodes CE1, CE2, and CE3 in a direction perpendicular to the substrate SUB or the third direction DR3. In addition, the tips TIP of the second bank layer BN2 may overlap the light emitting layers EL1, EL2, and EL3 in the direction DR3 perpendicular to the substrate SUB. In addition, the tips TIP of the second bank layer BN2 may overlap the pixel defining layer PDL in the direction DR3 perpendicular to the substrate SUB. The common electrodes CE1, CE2, and CE3 may be formed under the lower surfaces of the tips TIP of the second bank layer BN2. A maximum vertical distance from the substrate SUB to each of the common electrodes CE1, CE2, and CE3 may be smaller than a maximum vertical distance from the substrate SUB to the second bank layer BN2.

The thin film encapsulation layer TFEL may be disposed on the light emitting elements ED1, ED2, and ED3 and the bank structure BNS, and may cover the plurality of light emitting elements ED1, ED2, and ED3 and the bank structure BNS. The thin film encapsulation layer TFEL may include at least one inorganic film to prevent oxygen or moisture from permeating into the light emitting element layer EML. The thin film encapsulation layer TFEL may include at least one organic layer to protect the light emitting element layer EML from foreign substances such as dust.

In an embodiment, the thin film encapsulation layer TFEL may include a first inorganic encapsulation layer TFE1, an organic encapsulation layer TFE2, and a second inorganic encapsulation layer TFE3 that are sequentially stacked.

Each of the first inorganic encapsulation layer TFE1 and the second inorganic encapsulation layer TFE3 may include one or more inorganic insulating materials. The inorganic insulating material may include at least one selected from silicon oxide, silicon nitride, and silicon oxynitride, and may be, for example, aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. The polymer-based material may include an acrylic resin, an epoxy-based resin, polyimide, polyethylene, and the like. In an embodiment, for example, the organic encapsulation layer TFE2 may include an acrylic resin such as polymethyl methacrylate or polyacrylic acid. The organic encapsulation layer TFE2 may be formed by curing a monomer or applying a polymer.

The first inorganic encapsulation layer TFE1 may be disposed on the light emitting elements ED1, ED2, and ED3 and the bank structure BNS. The first inorganic encapsulation layer TFE1 may include a first inorganic layer TL1, a second inorganic layer TL2, and a third inorganic layer TL3 disposed to each correspond to the different emission areas EA1, EA2, and EA3. The first inorganic layer TL1, the second inorganic layer TL2, and the third inorganic layer TL3 may include an inorganic insulating material and cover the light emitting elements ED1, ED2, and ED3, respectively. The first inorganic layer TL1, the second inorganic layer TL2, and the third inorganic layer TL3 may prevent the light emitting elements ED1, ED2, and ED3 from being damaged by external air.

The first inorganic encapsulation layers TFE1 (TL1, TL2, and TL3) may be formed through chemical vapor deposition (CVD), and may thus be formed along steps of layers on which they are deposited. In an embodiment, for example, the first inorganic layer TL1, the second inorganic layer TL2, and the third inorganic layer TL3 may form thin films even under the undercuts by the tips TIP of the bank structure BNS. In an embodiment, as illustrated in FIGS. 4 to 6, the first inorganic encapsulation layers TL1, TL2, and TL3 may seal the light emitting elements ED1, ED2, and ED3 along outer surfaces of the light emitting elements ED1, ED2, and ED3 at a non-uniform thickness, but not being limited thereto. Alternatively, the first inorganic encapsulation layers TL1, TL2, and TL3 may be disposed along an upper surface, side surfaces, and a lower surface of the second bank layer BN2, side surfaces of the first bank layer BN1, and upper surfaces of the common electrodes CE1, CE2, and CE3 at a uniform thickness.

The first inorganic layer TL1 may not overlap the second opening and the third opening, and may be disposed only in the first opening, and on the first light emitting element ED1, and on the bank structure BNS around the first opening and the first light emitting element ED1. The second inorganic layer TL2 may not overlap the first opening and the third opening, and may be disposed only in the second opening, and on the second light emitting element ED2, and on the bank structure BNS around the second opening and the second light emitting element ED2. The third inorganic layer TL3 may not overlap the first opening and the second opening, and may be disposed only in the third opening, and on the third light emitting element ED3, and on the bank structure BNS around the third light emitting element ED3.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be disposed to be spaced apart from each other on the bank structure BNS.

The first inorganic encapsulation layers TL1, TL2, and TL3 may include main portions TL1_M and TL2_M surrounded by the bank structure BNS, wing portions TL1_W and TL2_W spaced apart from the upper surface of the second bank layer BN2 and overlapping the second bank layer BN2 in the thickness direction DR3 of the substrate SUB, and connection portions TL1_C and TL2_C respectively connecting the main portions TL1_M and TL2_M, and wing portions TL1_W and TL2_W. Although the main portions, wing portions, and connection portions of the third inorganic layer TL3 are not shown in the drawings, it will be understood by those of ordinary skill in the art that the main portions, wing portions, and connection portions of the third inorganic layer TL3 are substantially the same as the main portions TL1_M and TL2_M, the wing portions TL1_W and TL2_W, and connection portions TL1_C and TL2_C of the first and second inorganic layer TL1 and TL2 shown in FIG. 5.

The main portions TL1_M and TL2_M of the first inorganic encapsulation layers TL1, TL2, and TL3 may be in contact with the lower surface of the second bank layer BN2 and the side surfaces of the first bank layer BN1, and may cover the capping layers CAP and the common electrodes CE1, CE2, and CE3. The wing portions TL1_W and TL2_W of the first inorganic encapsulation layers TL1, TL2, and TL3 may be areas overlapping the second bank layer BN2 on the top portion of the second bank layer BN2. The width d2 of each of the wing portions TL1_W and TL2_W may be a maximum distance, that is, a maximum width of an area where the first inorganic encapsulation layers TL1, TL2, and TL3 on the top portion of the second bank layer BN2 and the second bank layer BN2 overlaps in the first direction DR1. The width d2 of the wing portion may be the same throughout the first to third inorganic layers TL1, TL2, and TL3, or may be different from each other.

The fillers FIL1, FIL2, and FIL3 may be disposed on the second bank layer BN2 and may be disposed between the first inorganic encapsulation layers TL1, TL2, and TL3. The fillers FIL1, FIL2, and FIL3 may fill a space between the upper surface of the second bank layer BN2 and the wing portions TL1_W and TL2_W of the first inorganic encapsulation layers TL1, TL2, and TL3. The exposed side of the connection portions TL1_C and TL2_C of the first inorganic encapsulation layers TL1, TL2, and TL3 may be covered by the fillers FIL1, FIL2, and FIL3.

Each of the fillers FIL1, FIL2, and FIL3 may have a first side surface FIL1_S11 adjacent to a corresponding one of the connection portions TL1_C and TL2_C of the first inorganic encapsulation layers TL1, TL2, and TL3, or a side surface of the second bank layer BN2, or a tip TIP. The fillers FIL1, FIL2, and FIL3 may have a second side surface FIL1_S21 which is a surface opposite to the first side surface FIL1_S11.

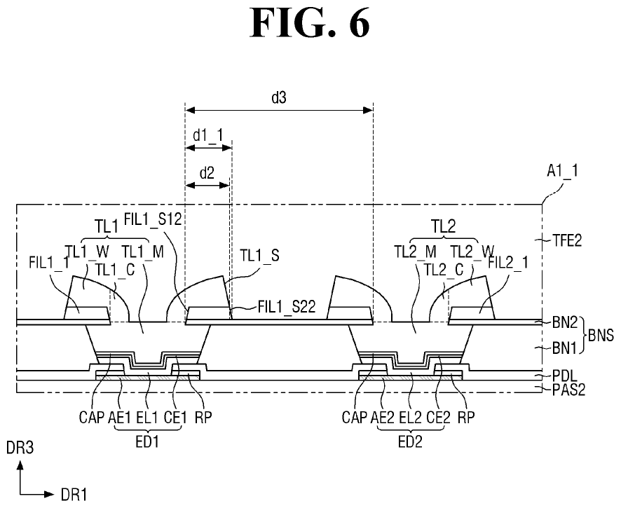

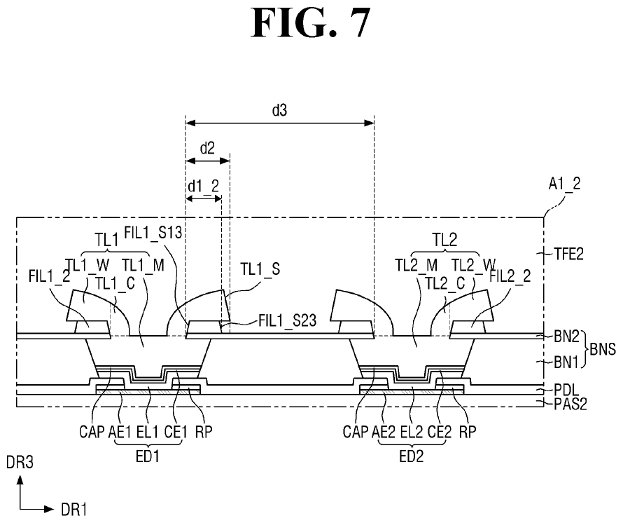

The width d1 of the fillers FIL1, FIL2, and FIL3 may be the maximum distance in the first direction DR1 in a cross-sectional view. FIG. 5 shows an embodiment where the width d1 of the fillers FIL1, FIL2, and FIL3 is greater than the width d2 of the wing portions TL1_W and TL2_W of the first inorganic encapsulation layer, and second side surface FIL1_S21 of each of the fillers FIL1, FIL2, and FIL3 protrudes more than the side surface TL1_S of each of the first inorganic encapsulation layers TL1, TL2, and TL3, respectively, in a direction opposite to the direction toward the center of the corresponding one of the emission areas EA1, EA2, and EA3. FIG. 6 shows an embodiment where a width d1_1 of each of the fillers FIL1, FIL2, and FIL3 is the same as or similar to the width d2 of each of the wing portions TL1_W and TL2_W of the first inorganic encapsulation layer, and a second side surface FIL1_S22 of each of the fillers FIL1, FIL2, and FIL3 are aligned with a side surface TL1_S of each of the first inorganic encapsulation layers TL1, TL2, and TL3, respectively to forma flat surface. FIG. 7 shown another embodiment where a width d1_2 of each of the fillers FIL1, FIL2, and FIL3 is less than the width d2 of each of the wing portions TL1_W and TL2_W of the first inorganic encapsulation layer, and the side surface TL1_S of each of the first inorganic encapsulation layer TL1, TL2, and TL3 protrudes more than a second side surface FIL1_S23 of each of the fillers FIL1, FIL2, and FIL3, respectively, in the direction opposite to the direction toward the center of the corresponding one of the emission areas EA1, EA2, and EA3. Here, the fact that side A protrudes more than side B can refer to a case where side A is located outside of the extended side of side B.

In an embodiment, after the first light emitting layer EL1, the first common electrode CE1, and the first inorganic layer TL1 are formed in the first emission area EA1, the second light emitting layer EL2, the second common electrode CE2, and the second inorganic layer TL2 may be formed in the second emission area EA2. In such an embodiment, materials are entirely deposited on the substrate, and thus, a second light emitting material layer ELL2, a second electrode material layer CEL2, and a second inorganic material layer TLL2 may be formed on the first inorganic layer TL1 covering the first emission area EA1 and the periphery of the first emission area EA1. The second light emitting material layer ELL2 may include or be made of a same material as the second light emitting layer EL2, and the second electrode material layer CEL2 may include or be made of a same material as the second common electrode CE2.

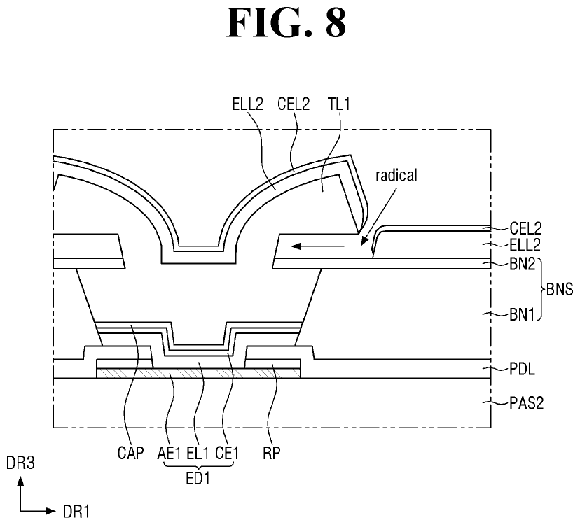

In a case where no fillers FIL1, FIL2, and FIL3 is provided on the top surface of the second bank layer BN2 and between the first inorganic encapsulation layers TL1, TL2, and TL3, due to the undercut structure under the wing portion TL1_W of the first inorganic layer TL1, the second light emitting material layers ELL2 and the second electrode material layers CEL2 are disconnected from each other and have a gap formed therebetween, at a boundary of the first inorganic layer TL1 as illustrated in FIG. 8. After the second inorganic material layer TLL2 is formed above the second light emitting material layer ELL2 and the second electrode material layer CEL2, only the second inorganic layer TL2 disposed in the second emission area EA2 and around the second emission area EA2 is left, and the second inorganic material layer TLL2 disposed in the remaining areas is removed through an etching process. In this case, a radical of an etchant for removing the second inorganic material layer TLL2 may penetrate into the gap between the second light emitting material layers ELL2 and the second electrode material layers CEL2 that are disconnected from each other. The radical penetrating into the gap removes the first inorganic layer TL1 and weakens adhesion or encapsulation between the bank structure BNS and the first inorganic layer TL1. This may cause damage to the first light emitting element ED1 and become a dark spot in the display device 10.

In an embodiment, the fillers FIL1, FIL2, and FIL3 are disposed on the top surface of the second bank layer BN2 and between the first inorganic encapsulation layers TL1, TL2, and TL3, such that the second light emitting material layer ELL2 and the second electrode material layer CEL2 may completely cover the outer surface of the first inorganic layer TL1, a first filler FIL1, and the second bank layer BN2 without being disconnected. In such an embodiment, as the first filler FIL1 is disposed, step coverage may be improved. The first inorganic layer TL1 is surrounded by the first filler FIL1 and/or the second light emitting material layer ELL2 and thus, is not exposed to the etchant. Accordingly, in such an embodiment, damage to the first light emitting element ED1 may be effectively prevented, and a luminance difference between the light emitting elements ED1, ED2, and ED3 may be reduced.

The width d1 of the fillers FIL1, FIL2, and FIL3 may be greater or less than, or substantially equal to the width d2 of the wing portions TL1_W and TL2_W of the first inorganic encapsulation layers TL1, TL2, and TL3. In an embodiment where the width d1 of the fillers FIL1, FIL2, and FIL3 is greater than the width d2 of the wing portions TL1_W and TL2_W of the first inorganic encapsulation layer, the protrusion width d1_2 of the fillers FIL1, FIL2, and FIL3 may be defined as the width by which the second side surface FIL1_S21 of the fillers FIL1, FIL2, and FIL3 protrudes from the side surface TL1_S of the first inorganic encapsulation layer TL1, TL2, and TL3. In an embodiment where the value of the width d1 is greater than the values of the width d2, the effect of preventing infiltration of etchant or radicals can be maximized. In an embodiment, the width d1 of the fillers FIL1, FIL2, and FIL3 may be in a range of about 3,000 Å to about 200,000 Å. The width d1 of each of the first to third fillers FIL1, FIL2, and FIL3 may be the same as or different from each other.

A width d3 of the second bank layer BN2 may be the minimum distance of the area that is not covered by the second bank layer BN2 and is exposed in the cross-sectional view of FIG. 3. In an embodiment, the second bank layer BN2 may include one end and the other end (or an opposing end), the one end may be adjacent to the first common electrode CE1 or the first light emitting element ED1, and the other end (or the opposing end) may be adjacent to the second common electrode CE2 or the second light emitting element ED2 which is opposite to the one end. The width d3 of the second bank layer BN2 may be defined as the distance between one end and the other end (or the opposing end) of the second bank layer BN2. The width d3 of the second bank layer BN2 may be the same between the plurality of emission areas, or may vary between emission areas.

In an embodiment, a ratio (d2/d3) of the width d2 of the wing portions TL1_W and TL2_W of the first inorganic encapsulation layer with respect to the width d3 of the second bank layer BN2 may be in a range of 0.20 to 0.50. In such an embodiment where the ratio (d2/d3) is in the above range, the wing portions TL1_W and TL2_W may maintain the shape thereof without bending even during washing and etching processes.

In an embodiment, a ratio (d1/d3) of the width d1 of the fillers FIL1, FIL2, and FIL3 with respect to the width d3 of the second bank layer BN2 may be in a range of 0.15 to 0.50. In such an embodiment where the ratio (d1/d3) is in the of the above range, the fillers FIL1, FIL2, and FIL3 may be disposed adjacent to the connection portions TL1_C and TL2_C of the first inorganic encapsulation layers TL1, TL2, and TL3 and increase the adhesion to the first inorganic encapsulation layers TL1, TL2, and TL3, thereby preventing the infiltration of the etchant. In an embodiment where the first filler FIL1 and the second filler FIL2 disposed on the second bank layer BN2 each have a value of d1/d3 of 0.5, the entire upper surface of the second bank layer BN2 disposed between the first emission area EA1 and the second emission area EA2 may be covered with the first filler FIL1 and the second filler FIL2.

The first inorganic encapsulation layers TL1, TL2, and TL3 may be in contact with the first side surfaces FIL1_S11 and the upper surfaces of the fillers FIL1, FIL2, and FIL3 and the bottom surface of the second bank layer BN2 to prevent moisture infiltrating from the external air, or infiltration of plasma or etchant.

In an embodiment, the ratio ((d1−d2)/d3) of a protrusion width (d1−d2) of the fillers FIL1, FIL2, and FIL3 with respect to the width d3 of the second bank layer BN2 may be in a range of 0.02 to 0.20. In such an embodiment, the ratio ((d1−d2)/d3) is in the above range, the step coverage of the organic material layer and the electrode material layer may be improved and infiltration of an etchant or radicals may be effectively prevented.

The fillers FIL1, FIL2, and FIL3 fill the areas where the organic material layers ELL1, ELL2, and ELL3 and electrode material layers CEL1, CEL2, and CEL3 were formed and then removed, and the thicknesses of the fillers FIL1, FIL2, and FIL3 may be the same or be similar to a sum of the thickness of the light emitting layers EL1, EL2, and EL3 and the common electrodes CE1, CE2, and CE3. In an embodiment, the thickness of the fillers FIL1, FIL2, and FIL3 may be in a range of about 1,500 Å to about 2,500 Å.

The fillers FIL1, FIL2, and FIL3 may include organic materials. In an embodiment, the fillers FIL1, FIL2, and FIL3 may include at least one selected from polyimide, polyamide, benzocyclobutene, a phenolic resin, an acrylic resin, a methacrylic resin, polyisoprene, a vinyl-based resin, an epoxy-based resin, a urethane-based resin, a cellulose-based resin, and a perylene-based resin. The fillers FIL1, FIL2, and FIL3 may include an opaque material as well as a transparent material. The fillers FIL1, FIL2, and FIL3 may include or be made of an organic material different from that of the organic encapsulation layer TFE2.

The organic encapsulation layer TFE2 is disposed on the second bank layer BN2, the first inorganic encapsulation layers TL1, TL2, and TL3, and the fillers FIL1, FIL2, and FIL3. Portions of the organic encapsulation layer TFE2 may be disposed between the plurality of fillers FIL1, FIL2, and FIL3. Portions of the second bank layer BN2 may be in direct contact with the fillers FIL1, FIL2, and FIL3 and the organic encapsulation layer TFE2. In an embodiment where the value of the distance d2 is greater than the distance d1_2, a portion of the organic encapsulation layer TFE2 may be in contact with surfaces of the first inorganic encapsulation layers TL1, TL2, and TL3 facing the upper surface of the second bank layer BN2 and the upper surface of the second bank layer BN2.

The second inorganic encapsulation layer TFE3 may be disposed on the organic encapsulation layer TFE2. The second inorganic encapsulation layer TFE3 may include aluminum oxide, titanium oxide, tantalum oxide, hafnium oxide, zinc oxide, silicon oxide, silicon nitride, and/or silicon oxynitride.

Referring back to FIG. 4, the light blocking layer BM may be disposed on the thin film encapsulation layer TFEL. The light blocking layer BM may include a plurality of holes OPT1, OPT2, and OPT3 disposed to overlap the emission areas EA1, EA2, and EA3. In an embodiment, for example, a first hole OPT1 may be defined to overlap the first emission area EA1. A second hole OPT2 may be defined to overlap the second emission area EA2, and a third hole OPT3 may be defined to overlap the third emission area EA3. An area or a size of each of the holes OPT1, OPT2, and OPT3 may be greater than the area or the size of each of the emission areas EA1, EA2, and EA3. The holes OPT1, OPT2, and OPT3 of the light blocking layer BM may be defined or formed to be greater than the emission areas EA1, EA2, and EA3, and accordingly, the light emitted from the emission areas EA1, EA2, and EA3 may be viewed by a user not only from a front surface but also from side surfaces of the display device 10.

The light blocking layer BM may include a light absorbing material. In an embodiment, for example, the light blocking layer BM may include an inorganic black pigment or an organic black pigment. The inorganic black pigment may be carbon black, and the organic black pigment may include at least one selected from lactam black, perylene black, and aniline black, but the disclosure is not limited thereto. The light blocking layer BM may effectively prevent color mixing due to permeation of visible light between the first to third emission areas EA1, EA2, and EA3 to improve a color gamut of the display device 10.

The display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. In an embodiment, for example, the color filters CF1, CF2, and CF3 may be disposed on the light blocking layer BM including the plurality of holes OPT1, OPT2, and OPT3 disposed to correspond to the emission areas EA1, EA2, and EA3. The holes of the light blocking layer may be formed to overlap the emission areas EA1, EA2, and EA3 or the openings of the bank structures BNS, and may form light emitting areas through which the light emitted from the emission areas EA1, EA2, and EA3 is emitted. Each of the color filters CF1, CF2, and CF3 may have a greater area than each of the holes of the light blocking layer BM, and may completely cover the light emitting area formed by each of the holes.

The color filters CF1, CF2, and CF3 may include a first color filter CF1, a second color filter CF2, and a third color filter CF3 disposed to each correspond to the different emission areas EA1, EA2, and EA3. The color filters CF1, CF2, and CF3 may include colorants such as dyes or pigments absorbing light of wavelength bands other than light of a specific wavelength band, and may be disposed to correspond to the colors of the light emitting from the emission areas EA1, EA2, and EA3. In an embodiment, for example, the first color filter CF1 may be a red color filter disposed to overlap the first emission area EA1 and transmitting only the first light, which is the red light, therethrough. The second color filter CF2 may be a green color filter disposed to overlap the second emission area EA2 and transmitting only the second light, which is the green light, therethrough, and the third color filter CF3 may be a blue color filter disposed to overlap the third emission area EA3 and transmitting only the third light, which is the blue light, therethrough.

The plurality of color filters CF1, CF2, and CF3 may be spaced apart from other adjacent color filters CF1, CF2, and CF3 on the light blocking layer BM. The color filters CF1, CF2, and CF3 may have greater areas than the holes OPT1, OPT2, and OPT3 of the light blocking layer BM while covering the holes OPT1, OPT2, and OPT3 of the light blocking layer BM, respectively, but may have areas enough to be spaced apart from other color filters CF1, CF2, and CF3 on the light blocking layer BM. However, the disclosure is not limited thereto. The plurality of color filters CF1, CF2, and CF3 may be disposed to partially overlap other adjacent color filters CF1, CF2, and CF3. Different color filters CF1, CF2, and CF3 may overlap each other on a light blocking layer BM to be described later, which is an area that does not overlap the emission areas EA1, EA2, and EA3. In an embodiment of the display device 10, the color filters CF1, CF2, and CF3 are disposed to overlap each other, and accordingly, an intensity of reflected light by external light may be reduced. In such an embodiment, a color feeling of the reflected light by the external light may be controlled by adjusting an arrangement, shapes, areas, or the like, of the color filters CF1, CF2, and CF3 in a plan view.

The overcoat layer OC may be disposed on the color filters CF1, CF2, and CF3 to planarize upper ends of the color filters CF1, CF2, and CF3. The overcoat layer OC may be a colorless light transmitting layer that does not have a color of a visible light band. For example, the overcoat layer OC may include a colorless light transmitting organic material such as an acrylic resin.

Hereinafter, processes for fabrication of the display device 10 (i.e., processes for a method of fabricating the display device 10) according to an embodiment will be described with reference to other drawings.

FIGS. 9 to 20 are detailed cross-sectional views sequentially illustrating processes for fabrication of the display device according to an embodiment.

In FIGS. 9 to 20, processes of forming the bank structure BNS and the light emitting elements ED as the light emitting element layer EML and the thin film encapsulation layer TFEL of the display device 10 are schematically illustrated. Hereinafter, descriptions of detailed processes of forming respective layers among the processes for fabrication of the display device 10 will be omitted, and the order of forming the respective layers will be described.

Referring to FIG. 9, in an embodiment, a plurality of pixel electrodes AE1, AE2, and AE3 spaced apart from each other, sacrificial layers SFL, a pixel defining material layer PDLL, and a plurality of bank material layers BNL1 and BNL2 are entirely formed on the second passivation layer PAS2.

Although not illustrated in FIG. 9, the thin film transistor layer TFTL may be disposed on the substrate SUB, and a structure of the thin film transistor TFTL is the same as that described above with reference to FIG. 4. Any repetitive detailed description thereof will be omitted.

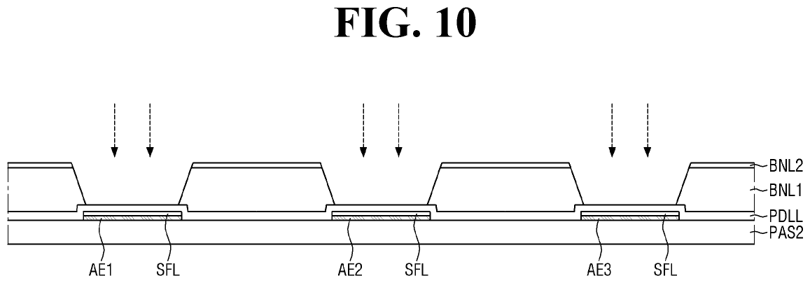

Subsequently, referring to FIG. 10, a photoresist (not illustrated) is formed on a second bank material layer BNL2, and a first etching process of etching portions of first and second bank material layers BNL1 and BNL2 using the photoresist PR as a mask is performed. Holes may be formed through the first etching process. The photoresists may be disposed to be spaced apart from each other on the second bank material layer BNL2, and may be disposed to expose areas overlapping the plurality of pixel electrodes AE1, AE2, and AE3.

In an embodiment, anisotropic dry etching may be performed as the first etching process. The holes may be formed in the areas overlapping the plurality of pixel electrodes AE1, AE2, and AE3, and may form the openings of the bank structure BNS.

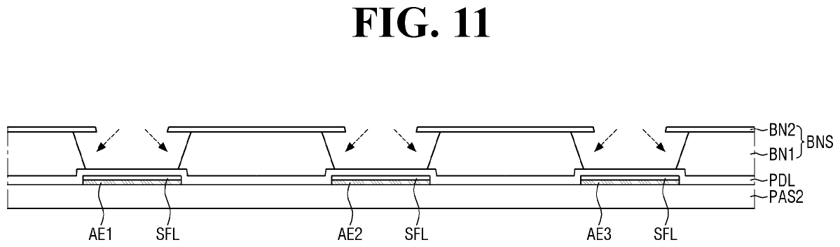

Next, referring to FIG. 11, undercut structures of the first bank layer BN1 may be formed through a second etching process. The first bank material layer BNL1 may have a faster (or higher) etch rate than the second bank material layer BNL2, and side surfaces of the second bank layer BN2 may be formed to protrude more than side surfaces of the first bank layer BN1. The side surfaces of the second bank layer BN2 protrude more than the side surfaces of the first bank layer BN1 toward the holes HOL to form tips TIP, and undercuts may be formed under the tips TIP.

In an embodiment, the second etching process may be isotropic wet etching. In the second etching process, an alkali-based etchant may be used. The bank structure BNS including the first and second bank layers BN1 and BN2 may be obtained through the second etching process.

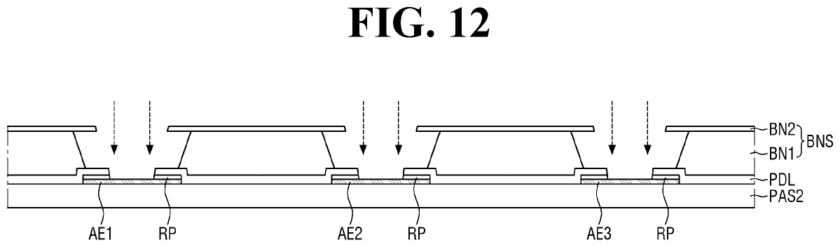

Subsequently, as illustrated in FIG. 12, the pixel defining material layer PDLL may be removed and the sacrificial layers SFL may also be removed, through a third etching process. The third etching process may include a dry etching step of removing the pixel defining material layer PDLL and a wet etching process of removing the sacrificial layers SFL.

The sacrificial layers SFL may protect the pixel electrodes AE1, AE2, and AE3 from plasma in the dry etching step. Portions of the sacrificial layers SFL exposed by the holes and portions of the sacrificial layers SFL between the first bank material layer BNL1 and the pixel electrodes AE1, AE2, and AE3 may be removed. However, the sacrificial layers SFL may not be completely removed, and may remain as partial residual patterns RP between the pixel defining layer PDL and the pixel electrodes AE1, AE2, and AE3.

The pixel electrodes AE1, AE2, and AE3 may be exposed through the third etching process. Thereafter, the photoresist (not illustrated) may be removed.

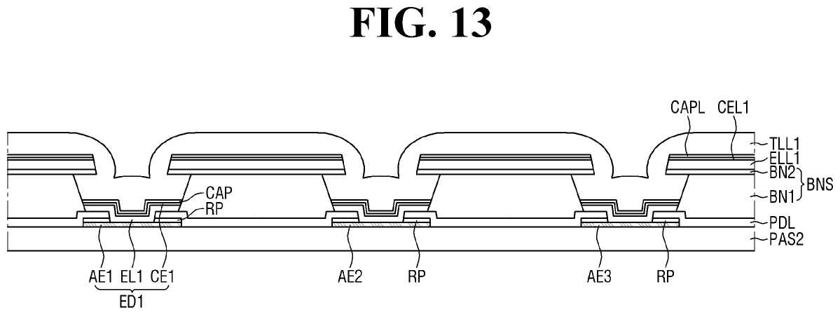

Subsequently, as illustrated in FIG. 13, the first light emitting layer EL1, the first common electrode CE1, and the capping layer CAP are deposited on the first pixel electrode AE1 to form the first light emitting element ED1. In this process, the first light emitting layer EL1, the first common electrode CE1, and the capping layer CAP are formed on the entire surface of the substrate SUB, and thus, a first light emitting material layer ELL1, a first electrode material layer CEL1, and a capping material layer CAPL may also be formed on the second bank layer BN2.

The first light emitting layer EL1 and the first light emitting material layer ELL1 may be separated from each other by the tips TIP of the second bank layer BN2, the first common electrode CE1 and the first electrode material layer CEL1 may be separated from each other by the tips TIP of the second bank layer BN2, and the capping layer CAP and the capping material layer CAPL may be separated from each other by the tips TIP of the second bank layer BN2. The first light emitting layer EL1 is formed on the first pixel electrode AE1, and at the same time, the first light emitting material layer ELL1 may be formed on the second bank layer BN2. The first common electrode CE1 is formed on the first light emitting layer EL1, and at the same time, the first electrode material layer CEL1 may be formed on the first light emitting material layer ELL1.

In an embodiment, the first light emitting layer EL1 and the first common electrode CE1 may be formed through deposition processes. Materials may not be smoothly deposited within the opening due to the tip TIP of the second bank layer BN2. However, materials of the first light emitting layer EL1 and the first common electrode CE1 are deposited in a direction inclined with an upper surface of the substrate rather than in the direction perpendicular to the upper surface of the substrate, and may thus be deposited in an area hidden or covered by the tip TIP of the second bank layer BN2.

The deposition process of forming the common electrodes CE1, CE2, and CE3 may be performed in an inclined direction relatively closer to a horizontal direction than the deposition process of forming the light emitting layers EL1, EL2, and EL3. Accordingly, the common electrodes CE1, CE2, and CE3 may be in contact with side surfaces of the first bank layer BN1 in a greater area than the light emitting layers EL1, EL2, and EL3. Alternatively, the common electrodes CE1, CE2, and CE3 may be deposited up to a higher position on the side surfaces of the first bank layer BN1 than the light emitting layers EL1, EL2, and EL3. Different common electrodes CE1, CE2, and CE3 may be in contact with the first bank layer BN1 having high conductivity to be electrically connected to each other.

Subsequently, a first inorganic material layer TLL1 covering the first light emitting element ED1 and the capping layer CAP is formed. The first inorganic material layer TLL1 may be formed to completely cover outer surfaces of the first light emitting element ED1, the bank layers BN1 and BN2, the capping layer CAP, the first light emitting material layer ELL1, the first electrode material layer CEL1, and the capping material layer CAPL without any disconnected portions. Specifically, the first inorganic material layer TLL1 is formed on an upper surface of the first common electrode CE1, an upper surface of the capping layer CAP, side surfaces of the first bank layer BN1, a lower surface and an upper surface of the second bank layer BN2, and upper surfaces of the first electrode material layer CEL1 and the capping material layer CAPL.

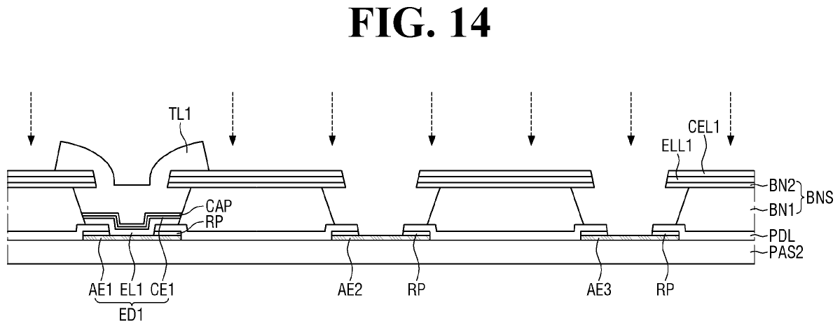

Next, referring to FIG. 14, a fourth etching process of exposing the first electrode material layer CEL1 is performed by removing a portion of the first inorganic material layer TLL1. In an embodiment, the fourth etching process may be an anisotropic dry etching. The first inorganic layer TL1 remains in an area overlapping the first emission area EA1 and an edge area surrounding the first emission area EA1, and the first inorganic material layer TLL1 in the remaining area is removed.

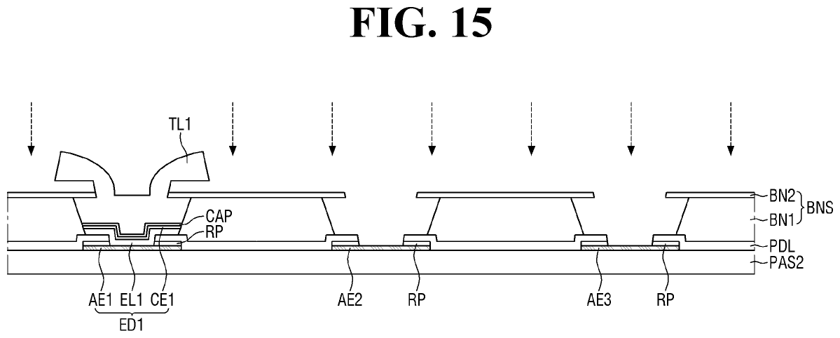

Subsequently, referring to FIG. 15, a fifth etching process for removing the first light emitting material layer ELL1 and the first electrode material layer CEL1 is performed to expose the second bank layer BN2. In an embodiment, the fifth etching process may be an isotropic wet etching operation. Not only the first electrode material layer CEL1 and the first light emitting material layer ELL1 disposed on the second bank layer BN2 but also the first light emitting material layer ELL1 and the first electrode material layer CEL1 of the second and third emission areas EA2 and EA3 not covered by the first inorganic material layer TLL1 may be removed. Therefore, the first light emitting material layer ELL1 and the first electrode material layer CEL1 disposed between the wing portion TL1_W of the first inorganic layer TL1 and the second bank layer BN2 may also be removed, and undercut structures of the first inorganic layer TL1 may be formed.

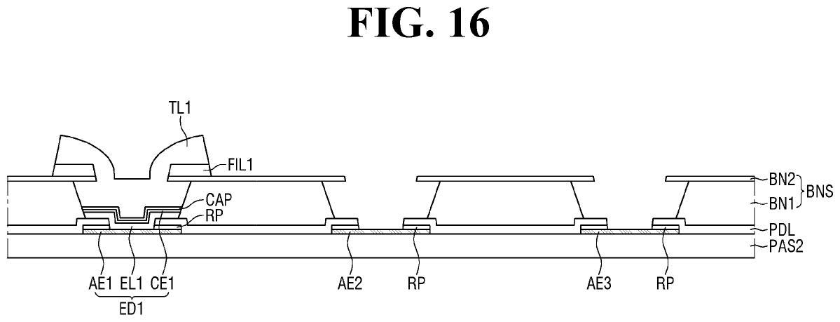

Next, as illustrated in FIG. 16, a first filler FIL1 may be formed. In an embodiment, the filler material is applied on the second bank layer BNL2 through slit coating, spin coating, or inkjet printing, such that the filler material may fill the undercut structure of the first inorganic layer TL1 due to capillary action. That is, the space between the second bank layer BN2 and the first inorganic layer TL1 may be filled with the first filler FILL. Thereafter, the width d1 of the first filler FIL1 may be adjusted by patterning the first filler FIL1 through a photolithography process. When the first inorganic layer TL1 is used as a mask, a second side surface FIL1_S22 of the first filler FIL1 is aligned with a side surface TL1_S of the first inorganic layer to form a flat surface as illustrated in FIG. 16. When using the photoresist covering the first inorganic layer TL1 and the surrounding area as a mask, a second side surface FIL1_S21 of the first filler FIL1 may protrude more than the side surface TL1_S of the first inorganic layer TL1 as illustrated in FIG. 5. In an embodiment, as described above, organic materials may be used as filler materials.

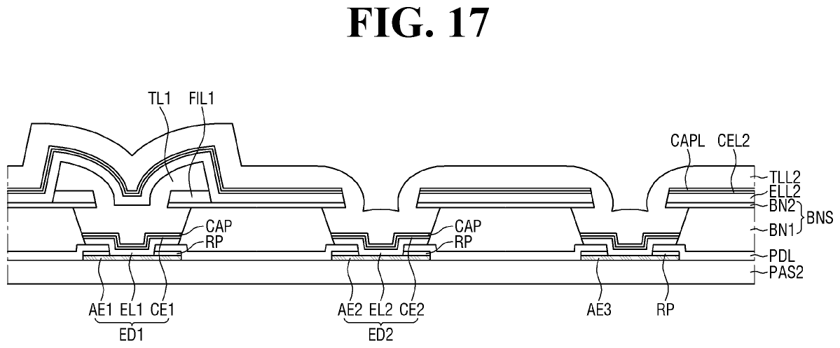

Subsequently, as illustrated in FIG. 17, the second light emitting layer EL2, the second common electrode CE2, and the capping layer CAP are deposited on the second pixel electrode AE2 to form the second light emitting element ED2. Thereafter, the second inorganic material layer TLL2 covering the second light emitting element ED2 and the capping layer CAP is formed. In this process, materials are deposited on the entire surface of the substrate SUB as in FIG. 15, and the second light emitting material layer ELL2 and the second electrode material layer CEL2 may cover the first inorganic layer TL1, the first filler FIL1, and the second bank layer BN2 without being disconnected. The second light emitting material layer ELL2 may include or be made of a same material as the second light emitting layer EL2.

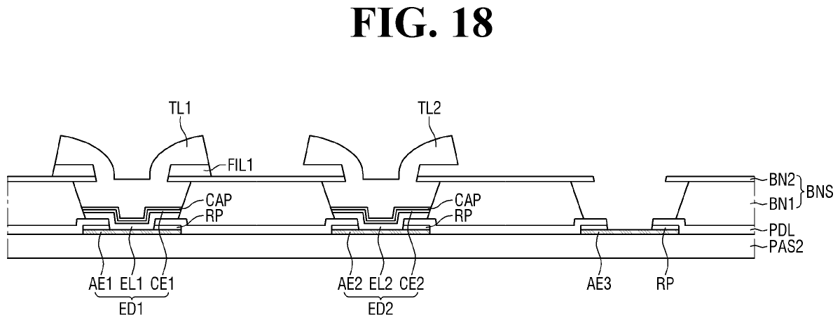

Next, as illustrated in FIG. 18, the second inorganic layer TL2 overlapping the second emission area EA2 and an edge surrounding the second emission area EA2 may be formed by removing a portion of the second inorganic material layer TLL2. This process may be performed similarly to the dry etching step of removing the first inorganic material layer TLL1 of FIG. 14. and wet etching step of removing the first electrode material layer CEL1 and the first light emitting material layer ELL1 of FIG. 15.

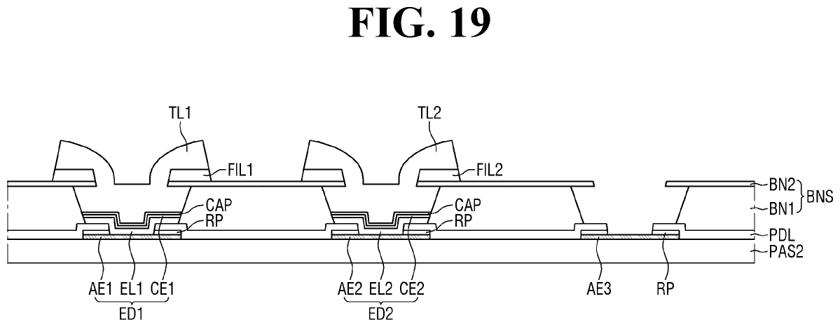

Next, as illustrated in FIG. 19, a second filler FIL2 may be formed in the undercut structure of the second inorganic layer TL2. This process may be performed similarly to the process shown in FIG. 16.

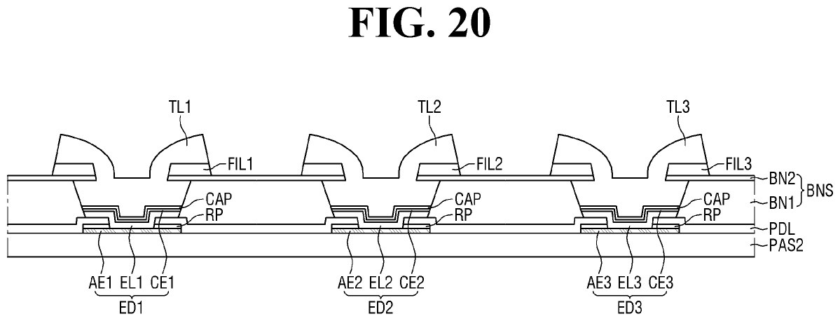

Thereafter, when the processes as illustrated in FIGS. 17 to 18 are similarly performed, a third light emitting element ED3 and a third inorganic layer TL3 may be formed on a third emission area EA3 as illustrated in FIG. 20.

Subsequently, although not illustrated in the drawings, the display device 10 is fabricated by forming the organic encapsulation layer TFE2 and the second inorganic encapsulation layer TFE3 of the thin film encapsulation layer TFEL, the light blocking layer BM, the color filter layer CFL, and the overcoat layer OC on the light emitting elements ED1, ED2, and ED3 and the bank structure BNS. Structures of the thin film encapsulation layer TFEL, the light blocking layer BM, the color filter layer CFL, and the overcoat layer OC are the same as those described above, and any repetitive detailed description thereof will thus be omitted.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first pixel electrode disposed on a substrate;
a pixel defining layer disposed on the substrate and exposing the first pixel electrode;
a first light emitting layer disposed on the first pixel electrode;
a first common electrode disposed on the first light emitting layer;
a first bank layer disposed on the pixel defining layer;
a second bank layer disposed on the first bank layer, wherein side surfaces of the second bank layer protrude more toward a center of a corresponding light emitting area than side surfaces of the first bank layer corresponding thereto do;
a first inorganic layer disposed on the first common electrode and the second bank layer, wherein the first inorganic layer is spaced apart from an upper surface of the second bank layer; and
a first filler disposed between the second bank layer and the first inorganic layer, wherein the first filler comprises a material different from a material of the first light emitting layer.

2. The display device of claim 1,
wherein the first filler includes at least one selected from polyimide, polyamide, benzocyclobutene, a phenolic resin, an acrylic resin, a methacrylic resin, polyisoprene, a vinyl-based resin, an epoxy-based resin, a urethane-based resin, a cellulose-based resin, and a perylene-based resin.

3. The display device of claim 1,
wherein a width of the first filler is in a range of about 3,000 Å to about 200,000 Å.

4. The display device of claim 1,
wherein a thickness of the first filler is in a range of about 1,500 Å to about 2,500 Å.

5. The display device of claim 1, further comprising:
a second pixel electrode disposed on the substrate and spaced apart from the first pixel electrode;
a second light emitting layer disposed on the second pixel electrode;
a second common electrode disposed on the second light emitting layer and spaced apart from the first common electrode;
a second inorganic layer disposed on the second common electrode and the second bank layer, wherein the second inorganic layer is spaced apart from the upper surface of the second bank layer; and
a second filler disposed between the second bank layer and the second inorganic layer, wherein the second filler comprises a material different from a material of the second light emitting layer,
wherein one end of the second bank layer is adjacent to the first common electrode,
an opposing other end of the second bank layer is adjacent to the second common electrode,
a width of the second bank layer is a distance between the one end and the opposing end of the second bank layer,
the first inorganic layer comprises a wing portion spaced apart from the upper surface of the second bank layer and overlapping the second bank layer in a thickness direction of the substrate, and
a ratio of a width of the wing portion of the first inorganic layer with respect to a width of the second bank layer is in a range of 0.20 to 0.50.

6. The display device of claim 5,
wherein a ratio of the width of the first filler with respect to the width of the second bank layer is in a range of 0.15 to 0.50.

7. The display device of claim 1,
wherein the first filler comprises a first side surface adjacent to a side surface of the second bank layer, and a second side surface which is opposite to the first side surface, and
the second side surface of the first filler protrudes more than a side surface of the first inorganic layer corresponding thereto.

8. The display device of claim 1,
wherein the first filler comprises a first side surface adjacent to a side surface of the second bank layer, and a second side surface which is opposite to the first side surface, and
the second side surface of the first filler is aligned with a side surface of the first inorganic layer corresponding thereto to form a flat surface.

9. The display device of claim 1,
wherein the first filler comprises a first side surface adjacent to a side surface of the second bank layer, and a second side surface which is opposite to the first side surface, and
a side surface of the first inorganic layer protrudes more than the second side surface of the first filler corresponding thereto.

10. The display device of claim 7,
wherein the first inorganic layer is in contact with a first side surface and the upper surface of the first filler, and a lower surface of the second bank layer.

11. The display device of claim 1,
further comprising an organic encapsulation layer disposed on the first inorganic layer, and
wherein the organic encapsulation layer comprises a material different from a material of the first filler.

12. The display device of claim 5,
wherein the first and second common electrodes are spaced apart from each other, and
the first and second common electrodes are in contact with the side surfaces of the first bank layer.

13. The display device of claim 1,
further comprising a residual pattern,
wherein the pixel defining layer is spaced apart from the upper surface of the first pixel electrode, and
the residual pattern is disposed between the pixel defining layer and the upper surface of the first pixel electrode.

14. A display device comprising:
a first pixel electrode and a second pixel electrode, which are disposed on a substrate to be spaced apart from each other;
a pixel defining layer disposed on the substrate and exposing the first pixel electrode and the second pixel electrode;
a first light emitting layer disposed on the first pixel electrode, and a first common electrode disposed on the first light emitting layer;
a second light emitting layer disposed on the second pixel electrode, and a second common electrode disposed on the second light emitting layer;
a first bank layer disposed on the pixel defining layer;
a second bank layer disposed on the first bank layer, wherein side surfaces of the second bank layer protrude more toward a center of a corresponding light emitting area than side surfaces of the first bank layer corresponding thereto do;
a first inorganic layer disposed on the first common electrode and the second bank layer, wherein the first inorganic layer is spaced apart from an upper surface of the second bank layer;
a second inorganic layer disposed on the second common electrode and the second bank layer, wherein the second inorganic layer is spaced apart from the upper surface of the second bank layer, and spaced apart from the first inorganic layer; and
a first filler disposed between the second bank layer and the first inorganic layer, wherein the first filler comprises a first side surface adjacent to a side surface of the second bank layer and a second side surface which is opposite to the first side surface,
wherein the second side surface of the first filler protrudes more than a side surface of the first inorganic layer corresponding thereto.

15. The display device of claim 14,
further comprising an organic encapsulation layer disposed on the first filler, the second bank layer and the first inorganic layer,
wherein the second bank layer is in contact with the first filler and the organic encapsulation layer.

16. The display device of claim 14,
wherein one end of the second bank layer is adjacent to the first common electrode,
an opposing end of the second bank layer is adjacent to the second common electrode,
a width of the second bank layer is a distance between the one end and the opposing end of the second bank layer,
a protrusion width of the first filler is a width at which the second side surface of the first filler protrudes more than the side surface of the first inorganic layer, and
a ratio of the protrusion width of the first filler with respect to the width of the second bank layer is in a range of 0.02 to 0.20.

17. A display device comprising:
a first pixel electrode and a second pixel electrode disposed to be spaced apart from each other on a substrate;
a pixel defining layer disposed on the substrate and exposing the first pixel electrode and the second pixel electrode;
a first light emitting layer disposed on the first pixel electrode, and a first common electrode disposed on the first light emitting layer;
a second light emitting layer disposed on the second pixel electrode, and a second common electrode disposed on the second light emitting layer;
a first bank layer disposed on the pixel defining layer;
a second bank layer disposed on the first bank layer, wherein side surfaces of the second bank layer protrude more toward a center of a corresponding light emitting area than side surfaces of the first bank layer corresponding thereto do;
a first inorganic layer disposed on the first common electrode and the second bank layer, wherein the first inorganic layer is spaced apart from an upper surface of the second bank layer;
a second inorganic layer disposed on the second common electrode and the second bank layer, wherein the second inorganic layer is spaced apart from the upper surface of the second bank layer, and spaced apart from the first inorganic layer; and
a first filler disposed between the second bank layer and the first inorganic layer, wherein the first filler comprises a first side surface adjacent to a side surface of the second bank layer and a second side surface which is opposite to the first side surface,
wherein a side surface of the first inorganic layer protrudes more than the second side surface of the first filler corresponding thereto.

18. The display device of claim 17,
further comprising an organic encapsulation layer disposed on the first inorganic layer and the second inorganic layer,
wherein the organic encapsulation layer is in contact with a surface of the first inorganic layer facing the upper surface of the second bank layer.

19. A method of fabricating a display device, the method comprising:
forming pixel electrodes and sacrificial layers on a substrate, forming a pixel defining material layer on the sacrificial layers, forming a first bank material layer on the pixel defining material layer, and forming a second bank material layer on the first bank material layer, wherein the pixel electrodes are spaced apart from each other, and the sacrificial layers are disposed on the pixel electrodes;
exposing the pixel defining material layer by etching portions of the first bank material layer and the second bank material layer in areas overlapping the pixel electrodes;
etching side surfaces of the first bank material layer in a way such that portions of a lower surface of the second bank material layer are exposed;
exposing the pixel electrodes by etching an exposed portion of the pixel defining material layer and the sacrificial layers;
forming a first light emitting layer on a first pixel electrode of the pixel electrodes and forming a first organic material layer on the second bank material layer,
forming a first common electrode on the first light emitting layer and forming a first electrode material layer on the first organic material layer;
forming a first inorganic material layer on the first common electrode and the first electrode material layer;
exposing the first electrode material layer by etching a portion of the first inorganic material layer;
exposing a second bank material layer by etching an exposed portion of the first electrode material layer and the first organic material layer; and
forming a first filler on an exposed portion of the second bank material layer.

20. The method of claim 19,
wherein the forming the first filler on the exposed second bank material layer comprises:
applying a material of the first filler on the second bank material layer through slit coating, spin coating, or inkjet printing;
filling between the second bank material layer and the first inorganic material layer with a material of the first filler through a capillary action; and
patterning the first filler through a photolithography process.

21. The method of claim 19,
wherein the forming the first light emitting layer on the first pixel electrode of the pixel electrodes and the forming the first organic material layer on the second bank material layer comprises cutting an organic material deposited on the substrate by a protruding side surface of the second bank material layer to be disconnected from the first light emitting layer and the first organic material layer.

22. The method of claim 19,
wherein the exposing the first electrode material layer by etching the portion of the first inorganic material layer comprises removing the portion of the first inorganic material layer through a dry etching process, and
the exposing the second bank material layer by etching the exposed portion of the first electrode material layer and the first organic material layer comprises removing the exposed portion of the first electrode material layer and the first organic material layer through a wet etching process.
